(19) United States
(12) Patent Application Publication
(10) Pub. No.: US 2025/0048904 A1
(43) Pub. Date: Feb. 6, 2025

(54) DISPLAY DEVICE

(71) Applicant: Samsung Display Co., LTD., Yongin-si (KR)

(72) Inventors: Hoon KIM, Yongin-si (KR); Eon Young KIM, Yongin-si (KR); So Hyun SHIN, Yongin-si (KR); Su Min CHOI, Yongin-si (KR)

(21) Appl. No.: 18/611,654

(22) Filed: Mar. 20, 2024

(30) Foreign Application Priority Data
Jul. 31, 2023 (KR) 10-2023-0100097

(51) Int. Cl. H10K 59/80; H10K 59/122; H10K 59/38; H10K 59/40

(52) U.S. Cl. CPC H10K 59/8792; H10K 59/122; H10K 59/38; H10K 59/40

(57) ABSTRACT

A display device includes a light emitting element layer disposed on a substrate, where a plurality of emission areas is defined on the light emitting element layer, an encapsulation layer disposed on the light emitting element layer, a touch sensing layer disposed on the encapsulation layer, where the touch sensing layer includes a plurality of touch electrodes, a reflection reduction layer disposed on the touch sensing layer, and a window disposed on the reflection reduction layer. The reflection reduction layer includes a color filter layer disposed on the touch sensing layer, a bank layer disposed on the touch sensing layer between the color filter layers, a light blocking layer disposed on the bank layer, and a low refractive layer disposed on the color filter layer, and disposed adjacent to the light blocking layer.

This application claims priority to Korean Patent Application No. 10-2023-0100097, filed on Jul. 31, 2023, and all the benefits accruing therefrom under 35 U.S.C. 119, the content of which in its entirety is herein incorporated by reference.

### BACKGROUND

### 1. Field

Embodiments of the disclosure relate to a display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device include an organic light emitting display device including organic light emitting elements, an inorganic light emitting display device including inorganic light emitting elements such as inorganic semiconductors, and a micro light emitting display device including micro light emitting elements.

The organic light emitting element may include two opposing electrodes, and a light emitting layer interposed therebetween. The light emitting layer receives electrons and holes from the two electrodes and recombines them to generate excitons, and the generated excitons change from an excited state to a ground state, thereby emitting light.

The organic light emitting display device including organic light emitting elements is attracting attention as a next-generation display device because of being able to meet the high display quality demands such as wide viewing angle, high brightness and contrast, and quick response speed as well as being able to be made having a low power consumption, lightweight, and thin by not including an undesired power source such as a backlight unit.

### SUMMARY

Embodiments of the disclosure provide a display device that includes a color filter disposed on a light emitting element, and is capable of reducing reflection of external light and improving light emission efficiency.

However, embodiments of the disclosure are not restricted to the one set forth herein. The above and other embodiments of the disclosure will become more apparent to one of ordinary skill in the art to which the disclosure pertains by referencing the detailed description of the disclosure given below.

According to an embodiment of the disclosure, a display device includes a light emitting element layer disposed on a substrate, where a plurality of emission areas is defined on the light emitting element layer, an encapsulation layer disposed on the light emitting element layer, a touch sensing layer disposed on the encapsulation layer, where the touch sensing layer includes a plurality of touch electrodes, a reflection reduction layer disposed on the touch sensing layer, and a window disposed on the reflection reduction layer, where the reflection reduction layer comprises a color filter layer disposed on the touch sensing layer, a bank layer disposed on the touch sensing layer between the color filter layers, a light blocking layer disposed on the bank layer, and a low refractive layer disposed on the color filter layer, and disposed adjacent to the light blocking layer.

In an embodiment, a refractive index of the low refractive layer may be less than a refractive index of the window.

In an embodiment, a difference between the refractive index of the low refractive layer and the refractive index of the window is about 0.1 or greater.

In an embodiment, the low refractive layer may include a resin and hollow particles dispersed in the resin.

In an embodiment, a top surface of the low refractive layer and a top surface of the light blocking layer may collectively define a continuous top surface of the reflection reduction layer.

In an embodiment, the light blocking layer may define a plurality of holes overlapping the plurality of emission areas, respectively, and an area of each of the hole is greater than an area of a corresponding one of the emission areas.

In an embodiment, the bank layer and the color filter layer may be disposed in a same layer as each other, and the color filter layer may include a plurality of color filters.

In an embodiment, the bank layer may have a lateral side overlapping the plurality of emission areas with a taper angle in a range of about 30 degrees to about 90 degrees.

In an embodiment, a refractive index of the bank layer may be less than a refractive index of the color filter layer.

In an embodiment, the light emitting element layer may include a pixel electrode disposed on the substrate, a pixel defining layer covering an edge of the pixel electrode and defining the plurality of emission areas, a light emitting layer disposed on the pixel electrode, and a common electrode disposed on the light emitting layer, and the light blocking layer and the bank layer overlap the pixel defining layer.

In an embodiment, the low refractive layer may cover the light blocking layer, and is in contact with a top surface of the light blocking layer.

According to an embodiment of the disclosure, a display device includes a light emitting element layer disposed on a substrate, where a plurality of emission areas is defined on the light emitting element layer, an encapsulation layer disposed on the light emitting element layer, a touch sensing layer disposed on the encapsulation layer, where the touch sensing layer includes a plurality of touch electrodes, a reflection reduction layer disposed on the touch sensing layer, and a window disposed on the reflection reduction layer, where the reflection reduction layer comprises a color filter layer disposed on the touch sensing layer, a first light blocking layer disposed on the color filter layer, where a plurality of holes is defined through the first light blocking layer to overlap the plurality of emission areas, respectively, and a low refractive layer disposed on the color filter layer, and disposed between the first light blocking layers.

In an embodiment, the plurality of emission areas may include a first emission area, a second emission area, and a third emission area, and the color filter layer comprises a first color filter overlapping the first emission area, a second color filter overlapping the second emission area, and a third color filter overlapping the third emission area, where the first color filter transmits red light, the second color filter transmits blue light, and the third color filter transmits green light.

In an embodiment, the color filter layer may include a color pattern disposed between the first color filter and the first light blocking layer, and the color pattern may be a blue color filter which transmits blue light.

In an embodiment, the color pattern may overlap the first light blocking layer and may not overlap the plurality of emission areas.

In an embodiment, the display device may further include a second light blocking layer disposed on the touch sensing layer, disposed between the first color filter and the second color filter, between the second color filter and the third color filter, and between the third color filter and the first color filter.

In an embodiment, the second light blocking layer may overlap the first light blocking layer and may not overlap the plurality of emission areas.

According to an embodiment of the disclosure, a display device includes a light emitting element layer disposed on a substrate, where a plurality of emission areas is defined on the light emitting element layer, an encapsulation layer disposed on the light emitting element layer, a touch sensing layer disposed on the encapsulation layer, where the touch sensing layer includes a plurality of touch electrodes, a reflection reduction layer disposed on the touch sensing layer, and a window disposed on the reflection reduction layer, where the reflection reduction layer comprises a color filter layer disposed on the touch sensing layer, where the color filter layer includes a first color filter, a second color filter, and a third color filter, which are spaced apart from each other, a light blocking layer disposed on the touch sensing layer between the first to third color filters, where a plurality of holes is defined through the light blocking layer to overlap the plurality of emission areas, respectively, a color pattern disposed on the light blocking layer and not overlapping the plurality of holes, and a low refractive layer disposed on the first to third color filters, and disposed between the color patterns.

In an embodiment, the plurality of emission areas may include a first emission area, a second emission area, and a third emission area, the first color filter may overlap the first emission area and transmits red light, the second color filter may overlap the second emission area and transmits blue light, and the third color filter may overlap the third emission area and transmits green light.

In an embodiment, the color pattern may be a red color filter which transmits red light.

In a display device according to embodiments of the disclosure, a bank layer is formed between color filters to change a path of light emitted from a light emitting element layer upward, thereby improving light emission efficiency.

In such embodiments of the display device, a low refractive layer is formed between light blocking layers to change a path of external light incident from the outside, so that the external light may be absorbed by the light blocking layer. Accordingly, reflection of external light may be reduced.

However, effects according to the embodiments of the disclosure are not limited to those exemplified above and various other effects are incorporated herein.

### BRIEF DESCRIPTION OF THE DRAWINGS

The above and other features of embodiments of the disclosure will become more apparent by describing in detail embodiments thereof with reference to the accompanying drawings, in which:

FIG. 1 is a schematic plan view of an electronic device according to an embodiment;

FIG. 2 is a perspective view illustrating a foldable display device in a folded state according to an embodiment;

FIG. 3 is a perspective view illustrating the foldable display device of FIG. 2 in an unfolded state;

FIG. 4 is a perspective view illustrating a display device included in an electronic device according to an embodiment;

FIG. 5 is a cross-sectional view of the display device of FIG. 4 viewed from a side;

FIG. 6 is a plan view illustrating a display layer of a display device according to an embodiment;

FIG. 7 is a plan view illustrating a touch sensing layer of a display device according to an embodiment;

FIG. 8 is a plan view illustrating an arrangement of the emission areas in the first display area of the display device according to an embodiment;

FIG. 9 is a plan view illustrating an arrangement of color filters disposed in the first display area of FIG. 8;

FIG. 10 is a cross-sectional view taken along line X-X′ of FIG. 8;

FIG. 11 is a schematic cross-sectional view of a low refractive layer according to an embodiment;

FIG. 12 is a cross-sectional view schematically illustrating a reflection reduction layer according to an embodiment;

FIG. 13 is a cross-sectional view schematically illustrating a light blocking layer, a low refractive layer, and a window according to an embodiment;

FIG. 14 is a cross-sectional view schematically illustrating a display device according to another embodiment;

FIG. 15 is a cross-sectional view schematically illustrating a display device according to still another embodiment;

FIG. 16 is a cross-sectional view schematically illustrating a display device according to still another embodiment;

FIG. 17 is a cross-sectional view schematically illustrating a display device according to still another embodiment;

FIG. 18 is a diagram illustrating an optical path of external light incident on a display device; and

FIG. 19 is a diagram illustrating an emission path of internal light of a display device according to an embodiment.

### DETAILED DESCRIPTION

The invention will now be described more fully hereinafter with reference to the accompanying drawings, in which various embodiments are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings herein. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Each of the features of the various embodiments of the disclosure may be combined or combined with each other, in part or in whole, and technically various interlocking and driving are possible. Each embodiment may be implemented independently of each other or may be implemented together in an association.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

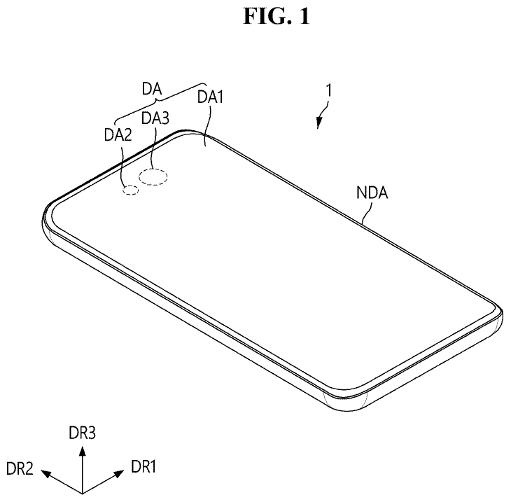

FIG. 1 is a schematic plan view of an electronic device according to an embodiment.

Referring to FIG. 1, an embodiment of an electronic device 1 displays a moving image or a still image. The electronic device 1 may refer to any electronic device that provides a display screen. Examples of the electronic device 1 may include a television, a laptop computer, a monitor, a billboard, an Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

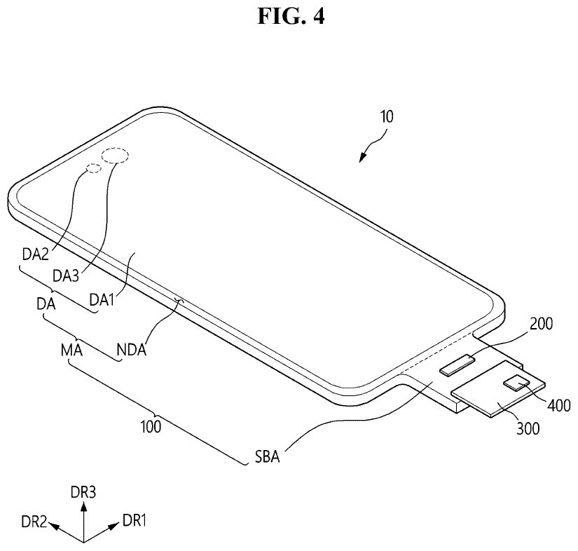

In an embodiment, the electronic device 1 may include a display device 10 (shown in FIG. 4) for providing a display screen. Examples of the display device may include an inorganic light emitting diode display device, an organic light emitting display device, a quantum dot light emitting display device, a plasma display device and a field emission display device. Hereinafter, for convenience of description, embodiments where an organic light emitting diode display device is applied as a display device will be described in detail, but the disclosure is not limited thereto, and other display devices may be applied within the same scope of technical spirit.

The shape of the electronic device 1 may be variously modified. In an embodiment, for example, the electronic device 1 may have a shape such as a rectangular shape elongated in a horizontal direction, a rectangular shape elongated in a vertical direction, a square shape, a quadrilateral shape with rounded corners (vertices), other polygonal shapes and a circular shape. The shape of a display area DA of the electronic device 1 may also be similar to the overall shape of the electronic device 1. FIG. 1 illustrates an embodiment of the electronic device 1 having a rectangular shape elongated in a second direction DR2.

The electronic device 1 may include the display area DA and a non-display area NDA. The display area DA is an area where an image can be displayed, and the non-display area NDA is an area where no image is displayed. The display area DA may also be referred to as an active region, and the non-display area NDA may also be referred to as a non-active region. The display area DA may substantially occupy the center of the electronic device 1.

The display area DA may include a first display area DA1, a second display area DA2, and a third display area DA3. The second display area DA2 and the third display area DA3 are areas in which components for adding various functions to the electronic device 1 are disposed, and the second display area DA2 and the third display area DA3 may correspond to a component area.

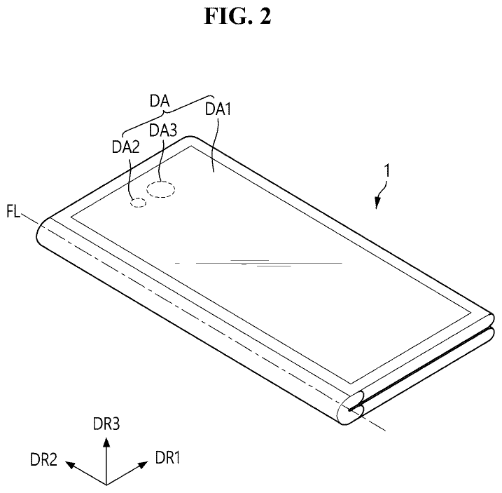

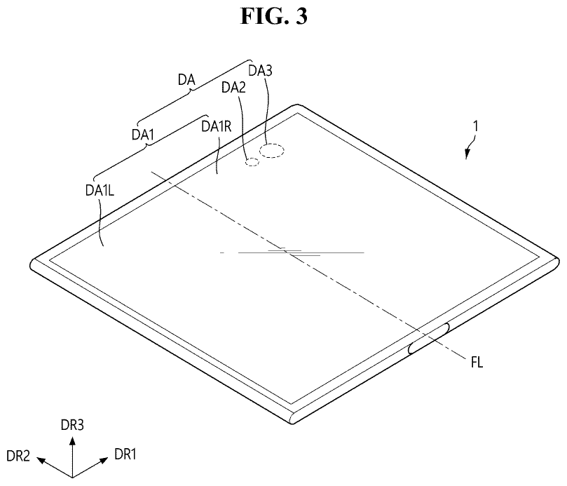

FIG. 2 is a perspective view illustrating a foldable display device in a folded state according to an embodiment. FIG. 3 is a perspective view illustrating the foldable display device of FIG. 2 in an unfolded state.

Referring to FIGS. 2 and 3, the electronic device 1 according to an embodiment may be a foldable display device. The foldable electronic device 1 may be folded around a folding axis FDL. The display area DA may be defined outside and/or inside (i.e., outer surfaces and inner surface) of the foldable electronic device 1. In an embodiment, the foldable electronic device 1 of FIGS. 2 and 3 illustrates that the display area DA is defined on each of the outside and the inside.

The display area DA may be defined outside the electronic device 1. An outer surface of the folded electronic device 1 may include the display area DA, and an inner surface of the unfolded electronic device 1 may include the display area DA. In the foldable electronic device 1 of FIG. 3, the display area DA may include a first display area DA1 that occupies most of the display area DA, and a second display area DA2 and a third display area DA3 that occupy relatively smaller areas than the first display area DA1. The first display area DA1 may include a first display portion DA1L and a second display portion DA1R positioned on both sides of the folding axis FDL. Each of the second display area DA2 and the third display area DA3 may be disposed in the area in which the second display portion DA1R is positioned, but is not limited thereto. In another embodiment, each of the second display area DA2 and the third display area DA3 may be disposed in the area in which the first display portion DA1L is positioned, or one of the second display area DA2 and the third display area DA3 may be disposed on the first display portion DA1L and the other may also be disposed on the second display portion DA1R.

In an embodiment, as illustrated in FIGS. 1 to 3, each of the second display area DA2 and the third display area DA3 may have a smaller area than the first display area DA1. The second display area DA2 and the third display area DA3 may have different sizes or areas, but are not limited thereto. In the drawings, embodiments in which the second display area DA2 has a smaller area than the third display area DA3 are shown as an example. Each of the second display area DA2 and the third display area DA3 may be surrounded by the first display area DA1. However, the disclosure is not limited thereto.

FIG. 4 is a perspective view illustrating a display device included in an electronic device according to an embodiment.

Referring to FIG. 4, the electronic device 1 according to an embodiment may include the display device 10. The display device 10 may provide a screen of the electronic device 1. The display device 10 may have a planar shape similar to the shape of the electronic device 1. In an embodiment, for example, the display device 10 may have a shape similar to a rectangular shape having a short side in a first direction DR1 and a long side in a second direction DR2. Here, a third direction DR3, which are perpendicular to a plane defined by the first direction DR1 and the second direction DR2, may be a thickness direction of the display device 10. The edge where the short side in the first direction DR1 and the long side in the second direction DR2 meet may be rounded to have a curvature, but is not limited thereto and may be formed at a right angle. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, and a touch driver 400.

The display panel 100 may include a main region MA and a sub-region SBA.

The main region MA may include the display area DA including pixels for displaying an image and the non-display area NDA disposed around the display area DA. The display area DA may include the first display area DA1, the second display area DA2, and the third display area DA3. The display area DA may emit light from a plurality of emission areas or a plurality of opening areas thereof. In an embodiment, for example, the display panel 100 may include a pixel circuit including switching elements, a pixel defining layer defining an emission area or an opening area, and a self-light emitting element.

In an embodiment, for example, the self-light emitting element may include at least one of an organic light emitting diode (LED) including an organic light emitting layer, a quantum dot LED including a quantum dot light emitting layer, an inorganic LED including an inorganic semiconductor, or a micro LED, but is not limited thereto.

The non-display area NDA may be an area outside the display area DA. The non-display area NDA may be defined as an edge area of the main region MA of the display panel 100. The non-display area NDA may include a gate driver (not illustrated) that supplies gate signals to the gate lines, and fan-out lines (not illustrated) that connect the display driver 200 to the display area DA.

The sub-region SBA may be a region extending from one side of the main region MA. The sub-region SBA may include a flexible material which can be bent, folded or rolled. In an embodiment, for example, when the sub-region SBA is bent, the sub-region SBA may overlap the main region MA in the thickness direction (the third direction DR3). The sub-region SBA may include the display driver 200 and a pad portion connected to the circuit board 300. In another embodiment, the sub-region SBA may be omitted, and the display driver 200 and the pad portion may be arranged in the non-display area NDA.

The display driver 200 may output signals and voltages for driving the display panel 100. The display driver 200 may supply data voltages to data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. In an embodiment, for example, the display driver 200 may be disposed in the sub-region SBA, and may overlap the main region MA in the thickness direction by bending of the sub-region SBA. In another embodiment, for example, the display driver 200 may be mounted on the circuit board 300.

The circuit board 300 may be attached to the pad portion of the display panel 100 by using an anisotropic conductive film (ACF). Lead lines of the circuit board 300 may be electrically connected to a pad portion of the display panel 100. The circuit board 300 may be a flexible printed circuit board, a printed circuit board, or a flexible film such as a chip on film.

A touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense an amount of change in capacitance between the plurality of touch electrodes. In an embodiment, for example, the touch driving signal may be a pulse signal having a predetermined frequency. The touch driver 400 may calculate whether an input is made and input coordinates based on an amount of change in capacitance between the plurality of touch electrodes. The touch driver 400 may be formed of or defined by an IC.

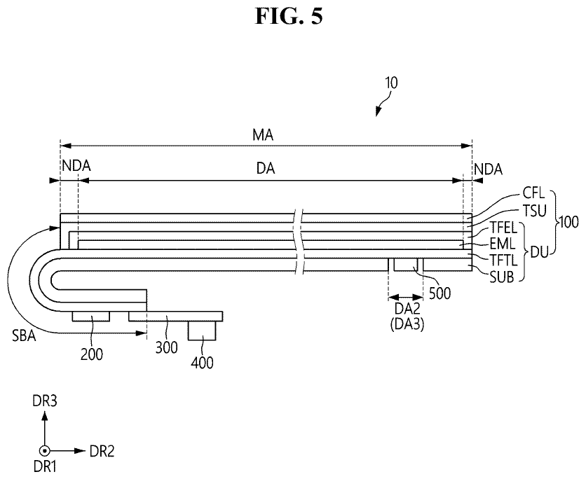

FIG. 5 is a cross-sectional view of the display device of FIG. 4 viewed from a side.

Referring to FIG. 5, an embodiment of the display panel 100 may include a display layer DU, a touch sensing layer TSU, and a color filter layer CFL. The display layer DU may include the substrate SUB, the thin film transistor layer TFTL, the light emitting element layer EML, and the encapsulation layer TFEL.

The substrate SUB may be a base substrate or a base member. The substrate SUB may be a flexible substrate which can be bent, folded or rolled. In an embodiment, for example, the substrate SUB may include a polymer resin such as polyimide (PI), but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. In an embodiment, for example, when the gate driver is formed on one side of the non-display area NDA of the display panel 100, the gate driver may include thin film transistors.

The thin film transistor layer TFTL may be disposed in the display area DA, the non-display area NDA, and the sub-region SBA. Thin film transistors, gate lines, data lines, and power lines of each of the pixels of the thin film transistor layer TFTL may be disposed in the display area DA. Gate control lines and fan-out lines of the thin film transistor layer TFTL may be disposed in the non-display area NDA. The lead lines of the thin film transistor layer TFTL may be disposed in the sub-region SBA.

The light emitting element layer EML may be disposed on the thin film transistor layer TFTL. The light emitting element layer EML may include a plurality of light emitting elements, each including a first electrode, a second electrode, and a light emitting layer to emit light, and a pixel defining layer defining pixels. The plurality of light emitting elements of the light emitting element layer EML may be disposed in the display area DA.

In an embodiment, the light emitting layer may be an organic light emitting layer including an organic material. The light emitting layer may include a hole transporting layer, an organic light emitting layer, and an electron transporting layer. When the first electrode receives a voltage through the thin film transistor of the thin film transistor layer TFTL and the second electrode receives the cathode voltage, holes and electrons may be transferred to the organic light emitting layer through the hole transporting layer and the electron transporting layer, respectively and may be combined with each other to emit light in the organic light emitting layer.

In another embodiment, the light emitting elements may include a quantum dot LED including a quantum dot light emitting layer, an inorganic LED including an inorganic semiconductor, or a micro LED.

The encapsulation layer TFEL may cover the top surface and the side surface of the light emitting element layer EML, and may protect the light emitting element layer EML. The encapsulation layer TFEL may include at least one inorganic layer and at least one organic layer for encapsulating the light emitting element layer EML.

The touch sensing layer TSU may be disposed on the encapsulation layer TFEL. The touch sensing layer TSU may include a plurality of touch electrodes for sensing a user's touch in a capacitive manner, and touch lines connecting the plurality of touch electrodes to the touch driver 400. In an embodiment, for example, the touch sensing layer TSU may sense the user's touch by using a mutual capacitance method or a self-capacitance method.

In another embodiment, the touch sensing layer TSU may be disposed on a separate substrate disposed on the display layer DU. In such an embodiment, the substrate supporting the touch sensing layer TSU may be a base member that encapsulates the display layer DU.

The plurality of touch electrodes of the touch sensing layer TSU may be disposed in a touch sensor area overlapping the display area DA. The touch lines of the touch sensing layer TSU may be disposed in a touch peripheral area that overlaps the non-display area NDA.

The color filter layer CFL may be disposed on the touch sensing layer TSU. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a portion of light coming from the outside of the display device 10 to reduce reflected light due to external light. Accordingly, the color filter layer CFL may prevent color distortion caused by reflection of the external light.

Since the color filter layer CFL is directly disposed on the touch sensing layer TSU, the display device 10 may not include a separate substrate for the color filter layer CFL. Accordingly, the thickness of the display device 10 may be relatively small.

In some embodiments, the display device 10 may further include an optical device 500. The optical device 500 may be disposed in the second display area DA2 or the third display area DA3. The optical device 500 may emit or receive light in infrared, ultraviolet, and visible light bands. In an embodiment, for example, the optical device 500 may be an optical sensor that detects light incident on the display device 10 such as a proximity sensor, an illuminance sensor, and a camera sensor or an image sensor.

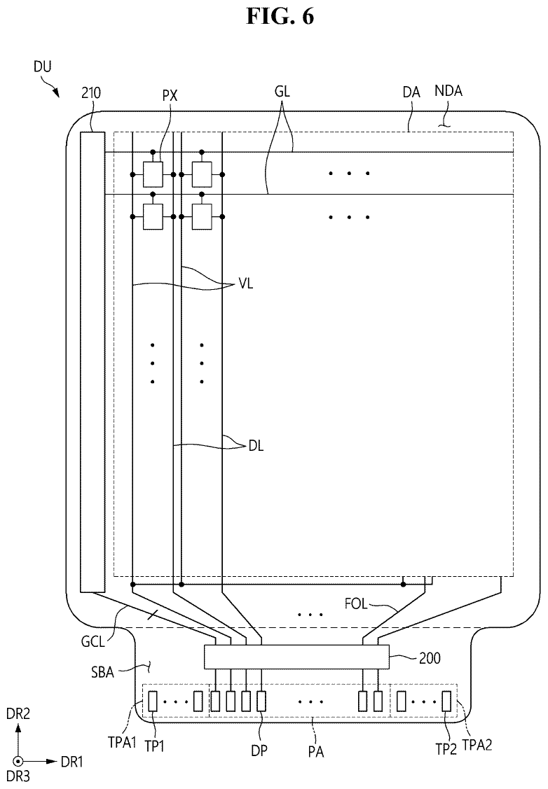

FIG. 6 is a plan view illustrating a display layer of a display device according to an embodiment.

Referring to FIG. 6, an embodiment of the display layer DU may include the display area DA and the non-display area NDA.

In an embodiment, the display area DA may be disposed at a central portion of the display panel 100. A plurality of pixels PX, a plurality of gate lines GL, a plurality of data lines DL, and a plurality of power lines VL may be disposed in the display area DA. Each of the plurality of pixels PX may be defined as a minimum unit that emits light.

The plurality of gate lines GL may supply the gate signals received from the gate driver 210 to the plurality of pixels PX. The plurality of gate lines GL may extend in the first direction DR1 and may be spaced apart from each other in the second direction DR2 intersecting the first direction DR1.

The plurality of data lines DL may supply the data voltages received from the display driver 200 to the plurality of pixels PX. The plurality of data lines DL may extend in the second direction DR2 and may be spaced apart from each other in the first direction DR1.

The plurality of power lines VL may supply the power voltage received from the display driver 200 to the plurality of pixels PX. Here, the power voltage may be at least one selected from a driving voltage, an initialization voltage, a reference voltage, and a low potential voltage. The plurality of power lines VL may extend in the second direction DR2 and may be spaced apart from each other in the first direction DR1.

The non-display area NDA may surround the display area DA. A gate driver 210, fan-out lines FOL, and gate control lines GCL may be disposed in the non-display area NDA. The gate driver 210 may generate a plurality of gate signals based on the gate control signal, and may sequentially supply the plurality of gate signals to the plurality of gate lines GL according to a set order.

The fan-out lines FOL may extend from the display driver 200 to the display area DA. The fan-out lines FOL may supply the data voltage received from the display driver 200 to the plurality of data lines DL.

The gate control line GCL may extend from the display driver 200 to the gate driver 210. The gate control line GCL may supply the gate control signal received from the display driver 200 to the gate driver 210.

The sub-region SBA may include the display driver 200, a pad area PA, and first and second touch pad areas TPA1 and TPA2.

The display driver 200 may output signals and voltages for driving the display panel 100 to the fan-out lines FOL. The display driver 200 may supply a data voltage to the data line DL through the fan-out lines FOL. The data voltage may be supplied to the plurality of pixels PX, and the luminance of the plurality of pixels PX may be controlled. The display driver 200 may supply the gate control signal to the gate driver 210 through the gate control line GCL.

The pad area PA, the first touch pad area TPA1, and the second touch pad area TPA2 may be disposed at the edge of the sub-region SBA. The pad area PA, the first touch pad area TPA1, and the second touch pad area TPA2 may be electrically connected to the circuit board 300 by using a material such as self assembly anisotropic conductive paste (SAP) or an anisotropic conductive film.

The pad area PA may include a plurality of display pad portions DP. The plurality of display pad portions DP may be connected to a graphic system through the circuit board 300. The plurality of display pad portions DP may be connected to the circuit board 300 to receive digital video data, and may supply the digital video data to the display driver 200.

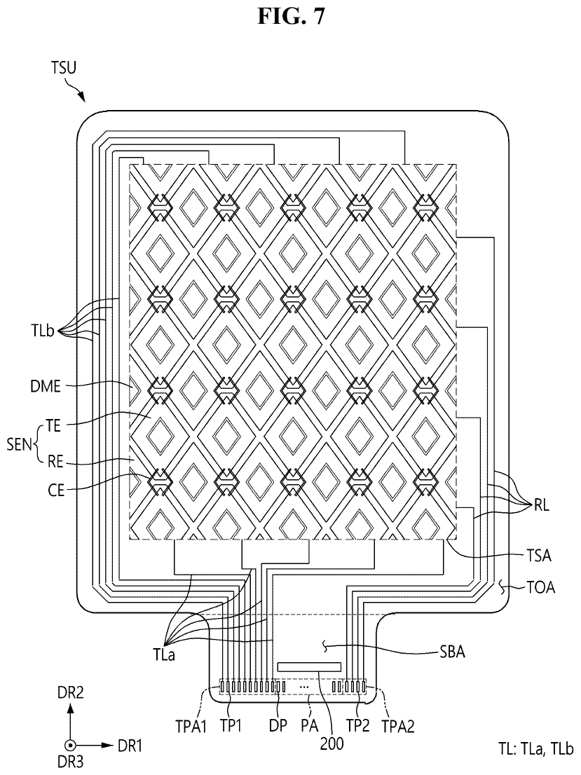

FIG. 7 is a plan view illustrating a touch sensing layer of a display device according to an embodiment.

Referring to FIG. 7, in an embodiment, the touch sensing layer TSU may include a touch sensor area TSA for sensing a user's touch, and a touch peripheral area TOA disposed around the touch sensor area TSA. The touch sensor area TSA may be disposed in the display area DA of the display device 10, and the touch peripheral area TOA may be disposed in the non-display area NDA of the display device 10.

The touch sensor area TSA may include a plurality of touch electrodes SEN and a plurality of dummy electrodes DME. The plurality of touch electrodes SEN may form mutual capacitance or self-capacitance to sense a touch of an object or a person. The plurality of touch electrodes SEN may include a plurality of driving electrodes TE and a plurality of sensing electrodes RE.

The plurality of driving electrodes TE may be arranged in the first direction DR1 and the second direction DR2. The plurality of driving electrodes TE may be spaced apart from each other in the first direction DR1 and the second direction DR2. The driving electrodes TE adjacent in the second direction DR2 may be electrically connected through a bridge electrode CE.

The plurality of driving electrodes TE may be connected to a first touch pad unit TP1 through a driving line TDL. The driving line TDL may include a lower driving line TLa and an upper driving line TLb. In an embodiment, for example, the driving electrodes TE disposed under the touch sensor area TSA may be connected to the first touch pad unit TP1 through the lower driving line TLa, and the driving electrodes TE disposed on the upper side of the touch sensor area TSA may be connected to the first touch pad unit TP1 through the upper driving line TLb. The lower driving line TLa may extend to the first touch pad unit TP1 through the lower side of the touch peripheral area TOA. The upper driving line TLb may extend to the first touch pad unit TP1 through the upper side, the left side, and the lower side of the touch peripheral area TOA. The first touch pad unit TP1 may be connected to the touch driver 400 through the circuit board 300.

The bridge electrode CE may be bent at least once. In an embodiment, for example, the bridge electrode CE may have an angle bracket-like shape (e.g., a shape of less-than sign or greater-than sign, i.e., “<” or “>”), but the planar shape of the bridge electrode CE is not limited thereto. The driving electrodes TE adjacent to each other in the second direction (Y-axis direction) may be connected by a plurality of bridge electrodes CE, and although any one of the bridge electrodes CE is disconnected, the driving electrodes TE may be stably connected through the remaining bridge electrode CE. The driving electrodes TE adjacent to each other may be connected by two bridge electrodes CE, but the number of bridge electrodes CE is not limited thereto.

The bridge electrode CE may be disposed in (or directly on) a different layer from the plurality of driving electrodes TE and the plurality of sensing electrodes RE. The sensing electrodes RE adjacent to each other in the first direction DR1 may be electrically connected through a connection portion disposed on the same layer as the plurality of driving electrodes TE or the plurality of sensing electrodes RE, and the driving electrodes TE adjacent in the second direction DR2 may be electrically connected through the bridge electrode CE disposed in (or directly on) a different layer from the plurality of driving electrodes TE or the plurality of sensing electrodes RE. Accordingly, although the bridge electrode CE overlaps the plurality of sensing electrodes RE in the Z-axis direction, the plurality of driving electrodes TE and the plurality of sensing electrodes RE may be insulated from each other. Mutual capacitance may be formed between the driving electrode TE and the sensing electrode RE.

The plurality of sensing electrodes RE may extend in the first direction DR1 and may be spaced apart from each other in the second direction DR2. The plurality of sensing electrodes RE may be arranged in the first direction DR1 and the second direction DR2, and the sensing electrodes RE adjacent in the first direction DR1 may be electrically connected through the connection portion.

The plurality of sensing electrodes RE may be connected to a second touch pad unit TP2 through a sensing line RL. In an embodiment, for example, the sensing electrodes RE disposed on the right side of the touch sensor area TSA may be connected to the second touch pad unit TP2 through the sensing line RL. The sensing line RL may extend to the second touch pad unit TP2 through the right side and the lower side of the touch peripheral area TOA. The second touch pad unit TP2 may be connected to the touch driver 400 through the circuit board 300.

Each of the plurality of dummy electrodes DME may be surrounded by the driving electrode TE or the sensing electrode RE. Each of the dummy electrodes DME may be insulated by being spaced apart from the driving electrode TE or the sensing electrode RE. Accordingly, the dummy electrode DME may be electrically floating.

The pad area PA, the first touch pad area TPA1, and the second touch pad area TPA2 may be disposed at the edge of the sub-region SBA. The pad area PA, the first touch pad area TPA1, and the second touch pad area TPA2 may be electrically connected to the circuit board 300 by using a low-resistance high-reliability material such as self assembly anisotropic conductive paste (SAP) or an anisotropic conductive film.

The first touch pad area TPA1 may be disposed on one side of the pad area PA, and may include a plurality of first touch pad units TP1. The plurality of first touch pad units TP1 may be electrically connected to the touch driver 400 disposed on the circuit board 300. The plurality of first touch pad units TP1 may supply a touch driving signal to the plurality of driving electrodes TE through a plurality of driving lines TDL.

The second touch pad area TPA2 may be disposed on the other side of the pad area PA, and may include a plurality of second touch pad units TP2. The plurality of second touch pad units TP2 may be electrically connected to the touch driver 400 disposed on the circuit board 300. The touch driver 400 may receive a touch sensing signal through a plurality of sensing lines RL connected to the plurality of second touch pad units TP2, and may sense a change in mutual capacitance between the driving electrode TE and the sensing electrode RE.

In another embodiment, the touch driver 400 may supply a touch driving signal to each of the plurality of driving electrodes TE and the plurality of sensing electrodes RE, and may receive a touch sensing signal from each of the plurality of driving electrodes TE and the plurality of sensing electrodes RE. The touch driver 400 may sense an amount of change in electric charge of each of the plurality of driving electrodes TE and the plurality of sensing electrodes RE based on the touch sensing signal.

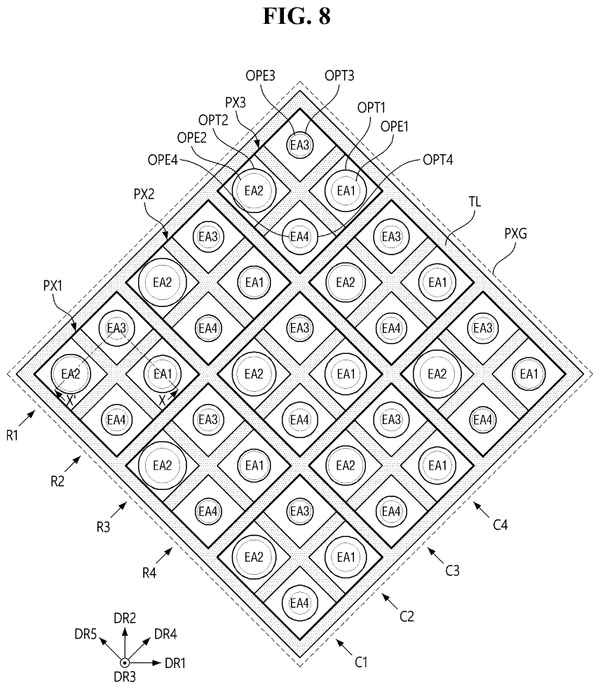

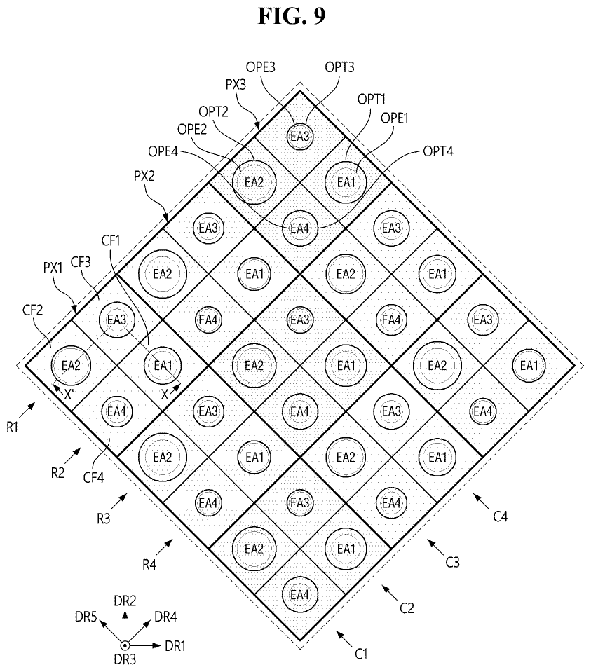

FIG. 8 is a plan view illustrating an arrangement of the emission areas in the first display area of the display device according to an embodiment. FIG. 9 is a plan view illustrating an arrangement of color filters disposed in the first display area of FIG. 8.

Referring to FIGS. 8 and 9, an embodiment of the display device 10 may include a plurality of pixels PX1, PX2, and PX3 disposed in the display area DA and emission areas EA1, EA2, EA3, and EA4 disposed in each of the pixels PX1, PX2, and PX3. The display area DA illustrated in FIGS. 8 and 9 is the first display area DA1, and the plurality of pixels PX1, PX2, and PX3 and the emission areas EA1, EA2, and EA3 may be disposed in the first display area DA1. In such an embodiment, the plurality of pixels PX1, PX2, and PX3 and the emission areas EA1, EA2, EA3, and EA4 may be disposed also in the second display area DA2 and the third display area DA3 of the display area DA.

The plurality of pixels PX1, PX2, and PX3 may be arranged in a fourth direction DR4 and a fifth direction DR5 between the first direction DR1 and the second direction DR2. The first pixel PX1, the second pixel PX2, and the third pixel PX3 may be alternately disposed along the fourth direction DR4 and the fifth direction DR5. In an embodiment, for example, the second pixel PX2 and the third pixel PX3 may be arranged in the fourth direction DR4 and the fifth direction DR5 with respect to the first pixel PX1. The plurality of pixels PX1, PX2, and PX3 may be disposed in a Pentile™ type, for example, a diamond Pentile™ type in the display area DA. However, the disposition or arrangement of the pixels PX1, PX2, and PX3 is not limited to those illustrated in FIGS. 5 and 6. In some embodiments, the plurality of pixels PX1, PX2, and PX3 may also be arranged in a linear or island-like pattern.

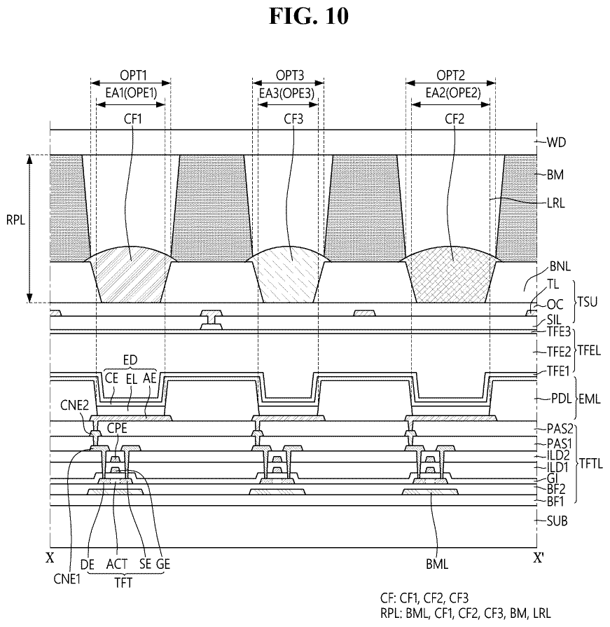

The emission areas EA1, EA2, EA3, and EA4 of each of the pixels PX1, PX2, and PX3 may include a first emission area EA1, a second emission area EA2, a third emission area EA3, and a fourth emission area EA4 that emit light of different colors. Unlike the first emission area EA1 and the second emission area EA2, the third emission area EA3 and the fourth emission area EA4 may emit light having the same color. Each of the first to fourth emission areas EA1, EA2, EA3, and EA4 may emit red, blue, or green light, and the color of the light emitted from each of the emission areas EA1, EA2, EA3, and EA4 may be different depending on the type of a light emitting element ED in FIG. 10 disposed on a light emitting element layer EML to be described later. In an embodiment, the first emission area EA1 may emit first light of a red color, the second emission area EA2 may emit third light of a blue color, and the third emission area EA3 and the fourth emission area EA4 may emit fourth light of a green color. However, the disclosure is not limited thereto.

The plurality of emission areas EA1, EA2, EA3, and EA4 may be disposed in a Pentile™ type, for example, a diamond Pentile™ type. In an embodiment, for example, in each of the pixels PX1, PX2, and PX3, the first emission area EA1 and the second emission area EA2 may be disposed to be spaced apart from each other in the first direction DR1, and the third emission area EA3 and the fourth emission area EA4 may be disposed to be spaced apart from each other in the second direction DR2. The first emission area EA1 may be disposed to be spaced apart from the third emission area EA3 in the fifth direction DR5, and may be disposed to be spaced apart from the fourth emission area EA4 in the fourth direction DR4. The second emission area EA2 may be disposed to be spaced apart from the third emission area EA3 in the fourth direction DR4, and may be disposed to be spaced apart from the fourth emission area EA4 in the fifth direction DR5.

In the plurality of pixels PX1, PX2, and PX3, the plurality of first to fourth emission areas EA1, EA2, EA3, and EA4 may be alternately disposed in the fourth direction DR4 or the fifth direction DR5. In an embodiment, for example, the plurality of emission areas EA1, EA2, EA3, and EA4 may be disposed in rows R1, R2, R3, and R4 arranged along the fourth direction DR4 and columns C1, C2, C3, and C4 arranged along the fifth direction DR5. In the first row R1 and the third row R3, the second emission area EA2 and the third emission area EA3 may be alternately disposed along the fourth direction DR4. In the second row R2 and the fourth row R4, the first emission area EA1 and the fourth emission area EA4 may be alternately disposed along the fourth direction DR4. In the first column C1 and the third column C3, the second emission area EA2 and the fourth emission area EA4 may be alternately disposed along the fifth direction DR5. In the second column C2 and the fourth column C4, the first emission area EA1 and the third emission area EA3 may be alternately disposed along the fourth direction DR4.

Alternatively, the plurality of emission areas EA1, EA2, EA3, and EA4 may be arranged along the first direction DR1 or the second direction DR2. The first emission area EA1 and the second emission area EA2 may be alternately disposed along the first direction DR1 and the second direction DR2. The third emission area EA3 and the fourth emission area EA4 may be alternately disposed along the first direction DR1 and the second direction DR2.

Each of the first to fourth emission areas EA1, EA2, EA3, and EA4 may be defined by a plurality of openings OPE1, OPE2, OPE3 and OPE4 formed in a pixel defining layer PDL (see FIG. 10) of the light emitting element layer EML to be described later. In an embodiment, for example, the first emission area EA1 may be defined by the first opening OPEL of the pixel defining layer, the second emission area EA2 may be defined by the second opening OPE2 of the pixel defining layer, the third emission area EA3 may be defined by the third opening OPE3 of the pixel defining layer, and the fourth emission area EA4 may be defined by the fourth opening OPE4 of the pixel defining layer.

In an embodiment, the areas or sizes of the first to fourth emission areas EA1, EA2, EA3, and EA4 may be different from each other. In an embodiment, as shown in FIG. 8, the area of the second emission area EA2 may be greater than the areas of the first emission area EA1, the third emission area EA3, and the fourth emission area EA4, and the area of the first emission area EA1 may be greater than the areas of the third emission area EA3 and the fourth emission area EA4. The areas of the emission areas EA1, EA2, EA3, and EA4 may vary according to the sizes of the openings OPE1, OPE2, OPE3, and OPE4 formed in the pixel defining layer. The intensity of light emitted from the corresponding emission areas EA1, EA2, EA3, and EA4 may vary according to the areas of the emission areas EA1, EA2, EA3, and EA4, and the areas of the emission areas EA1, EA2, EA3, and EA4 may be adjusted to control the color of the screen displayed on the display device 10 or the electronic device 1. In an embodiment, as shown in FIG. 8, the second emission area EA2 having the largest area is illustrated, but is not limited thereto. The areas of the emission areas EA1, EA2, EA3, and EA4 may be freely adjusted or various modified based on the color of the screen desired by the display device 10 and the electronic device 1. In addition, the areas of the emission areas EA1, EA2, EA3, and EA4 may be related to light efficiency and the lifespan of the light emitting element ED, and may have a trade-off relation with the reflection by external light. The areas of the emission areas EA1, EA2, EA3, and EA4 may be adjusted in consideration of the above factors.

Each of the plurality of pixels PX1, PX2, and PX3 may include the first to fourth emission areas EA1, EA2, EA3, and EA4 disposed adjacent to each other to express a white gray scale. However, the disclosure is not limited thereto, and the combination of the emission areas EA1, EA2, EA3, and EA4 constituting one pixel group may be variously modified depending on the arrangement of the emission areas EA1, EA2, and EA3, the color of the light emitted from the emission areas EA1, EA2, EA3, and EA4, and the like.

The display device 10 may include the plurality of color filters CF1, CF2, CF3, and CF4 disposed on the emission areas EA1, EA2, EA3, and EA4. The plurality of color filters CF1, CF2, CF3, and CF4 may be disposed to correspond to the emission areas EA1, EA2, EA3, and EA4, respectively. In an embodiment, for example, the color filters CF1, CF2, CF3, and CF4 may be disposed on a light blocking layer BM (see FIG. 10) including a plurality of holes OPT1, OPT2, OPT3, and OPT4 disposed to correspond to the emission areas EA1, EA2, EA3, and EA4 or the openings OPE1, OPE2, OPE3, and OPE4. The holes OPT1, OPT2, OPT3, and OPT4 of the light blocking layer may be defined or formed to overlap the openings OPE1, OPE2, OPE3, and OPE4, and may form a light exit area from which the light emitted from the emission areas EA1, EA2, EA3, and EA4 is emitted. Each of the color filters CF1, CF2, CF3, and CF4 may have a larger area than the holes OPT1, OPT2, OPT3, and OPT4 of the light blocking layer and the openings OPE1, OPE2, OPE3, and OPE4, and each of the color filters CF1, CF2, CF3, and CF4 may completely cover the light exit area formed by the holes OPT1, OPT2, OPT3, and OPT4.

The color filters CF1, CF2, CF3, and CF4 may include a first color filter CF1, a second color filter CF2, a third color filter CF3, and a fourth color filter CF4 disposed to correspond to the different emission areas EA1, EA2, EA3, and EA4, respectively. The color filters CF1, CF2, CF3, and CF4 may include a colorant such as a dye or a pigment that absorbs light in a wavelength band other than light in a specific wavelength band, and may be disposed to correspond to the color of the light emitted from the emission areas EA1, EA2, EA3, and EA4. In an embodiment, for example, the first color filter CF1 may be a red color filter that is disposed to overlap the first emission area EA1 and transmits only the first light of the red color. The second color filter CF2 may be a blue color filter that is disposed to overlap the second emission area EA2 and transmits only the second light of the blue color, the third color filter CF3 may be a green color filter that is disposed to overlap the third emission area EA3 and transmits only the third light of the green color, and the fourth color filter CF4 may be a green color filter that is disposed to overlap the fourth emission area EA4.

Similarly to the disposition of the emission areas EA1, EA2, EA3, and EA4, the color filters CF1, CF2, CF3, and CF4 may be disposed in a Pentile™ type, for example, a diamond Pentile™ type. In an embodiment, for example, in the plurality of pixels PX1, PX2, and PX3, the plurality of first to fourth color filters CF1, CF2, CF3, and CF4 may be alternately disposed in the fourth direction DR4 or the fifth direction DR5. For example, the plurality of color filters CF1, CF2, CF3, and CF4 may be disposed in the rows R1, R2, R3, and R4 arranged along the fourth direction DR4 and in the columns C1, C2, C3, and C4 arranged along the fifth direction DR5. In the first row R1 and the third row R3, the second color filter CF2 and the third color filter CF3 may be alternately disposed along the fourth direction DR4. In the second row R2 and the fourth row R4, the first color filter CF1 and the fourth color filter CF4 may be alternately disposed along the fourth direction DR4. In the first column C1 and the third column C3, the second color filter CF2 and the fourth color filter CF4 may be alternately disposed along the fifth direction DR5. In the second column C2 and the fourth column C4, the first color filter CF1 and the third color filter CF3 may be alternately disposed along the fourth direction DR4.

According to an embodiment, the plurality of color filters CF1, CF2, CF3, and CF4 may be disposed to partially overlap other adjacent color filters CF1, CF2, CF3, and CF4. FIG. 9 illustrates an embodiment where the color filters CF1, CF2, CF3, and CF4 adjacent to each other are disposed to abut each other, but as will be described later, the adjacent color filters CF1, CF2, CF3, and CF4 may partially overlap at the boundary in which the adjacent color filters CF1, CF2, CF3, and CF4 abut each other. FIG. 9 illustrates the disposition of the color filters CF1, CF2, CF3, and CF4 as viewed from above, that is, when viewed in the third direction DR3, and it would be understood that among the color filters CF1, CF2, CF3, and CF4 overlapping each other, the edges of the color filters CF1, CF2, CF3, and CF4 disposed below are covered by the color filters CF1, CF2, CF3, and CF4 disposed above the edges. The different color filters CF1, CF2, CF3, and CF4 are areas that do not overlap the emission areas EA1, EA2, EA3, and EA4, and may overlap each other on the light blocking layer BM to be described later.

In an embodiment of the display device 10, the color filters CF1, CF2, CF3, and CF4 are disposed to overlap each other, so that the intensity of the reflected light by external light may be reduced. In such an embodiment, the color of the reflected light by the external light may be controlled by adjusting the disposition, shape, and area of the color filters CF1, CF2, CF3, and CF4 in a plan view.

In an embodiment, as shown in FIG. 8, a touch electrode TL may be disposed between the emission areas EA1, EA2, EA3, and EA4. The touch electrode TL may be disposed to extend in the fourth direction DR4 and the fifth direction DR5, and may be spaced apart the emission areas EA1, EA2, EA3, and EA4 from without overlapping the emission areas EA1, EA2, EA3, and EA4. The touch electrode TL may be disposed to overlap the pixel defining layer PDL in FIG. 10 that defines the openings OPE1, OPE2, OPE3, and OPE4, and the light blocking layer BM (see FIG. 10) provided with the plurality of holes OPT1, OPT2, OPT3, and OPT4 to be described later. Although the touch electrode TL is briefly illustrated in FIG. 8, the touch electrode TL may be either the touch driving electrode TE or the sensing electrode RE of FIG. 7.

In an embodiment, as will be described later, the diameters of the openings OPE1, OPE2, OPE3, and OPE4 defining the emission areas EA1, EA2, EA3, and EA4 may be less than the diameters of the holes OPT1, OPT2, OPT3, and OPT4 of the light blocking layer BM. An opening width between the openings OPE1, OPE2, OPE3, and OPE4 and the holes OPT1, OPT2, OPT3, and OPT4 of the light blocking layer BM may be defined for each of the emission areas EA1, EA2, EA3, and EA4. The opening width may also be defined as a difference in diameter between the openings OPE1, OPE2, OPE3, and OPE4 of the pixel defining layer PDL and the holes OPT1, OPT2, OPT3, and OPT4 of the light blocking layer BM. In an embodiment of the display device 10, the same emission areas EA1, EA2, EA3, and EA4 of the different pixels PX1, PX2, and PX3 may have different opening widths between the openings OPE1, OPE2, OPE3, and OPE4 and the holes OPT1, OPT2, OPT3, and OPT4 of the light blocking layer BM. In the first pixel PX1, the second pixel PX2, and the third pixel PX3, the emission areas EA1, EA2, EA3, and EA4 may emit light of a same color as each other, but in each thereof, the opening widths between the openings OPE1, OPE2, OPE3, and OPE4 and the holes OPT1, OPT2, OPT3, and OPT4 of the light blocking layer BM may be different from each other.

In an embodiment, for example, each of the first to third pixels PX1, PX2, and PX3 may include the first emission area EA1 for emitting red light, but in the pixels PX1, PX2, and PX3, the opening widths of the first emission areas EA1 may be different from each other. In an embodiment, in the first to third pixels PX1, PX2, and PX3, the second to fourth emission areas EA2, EA3, and EA4 may also emit light of a same color, but may have opening widths different from each other. In addition, also in each of the pixels PX1, PX2, PX3, and PX4, the first to fourth emission areas EA1, EA2, EA3, and EA4 may have opening widths different from each other.

In an embodiment of the display device 10, the specific emission areas EA1, EA2, EA3, and EA4 may have at least three among the emission areas EA1, EA2, EA3, and EA4 in which the opening widths between the openings OPE1, OPE2, OPE3, and OPE4 and the holes OPT1, OPT2, OPT3, and OPT4 of the light blocking layer BM are different from each other. The display device 10 may have three or more types of the homogeneous openings or the homogeneous emission areas having different opening widths from each other. In an embodiment, for example, in the first pixel PX1, the second pixel PX2, and the third pixel PX3, the opening widths of the first emission areas EA1 may be different from each other. In an embodiment of the display area of the display device 10, three first emission areas EA1 having different opening widths from each other may be disposed, and the three first emission areas EA1 may be disposed in the first pixel PX1, the second pixel PX2, and the third pixel PX3, respectively. This may be the same in the case of the second to fourth emission areas EA2, EA3, and EA4.

In an embodiment, the display device 10 may include a pixel group PXG in which three first to third pixels PX1, PX2, and PX3 including the emission areas that are the same emission areas EA1, EA2, EA3, and EA4 but have different opening widths are disposed in a specific arrangement. In the display area DA of the display device 10, a plurality of pixel groups PXG may be arranged in the first direction DR1 and the second direction DR2, or the fourth direction DR4 and the fifth direction DR5, and the first to third pixels PX1, PX2, and PX3 may be disposed in a specific arrangement in one pixel group PXG. The pixel group PXG in FIG. 9 may have a structure in which the second pixel PX2 and the third pixel PX3 are disposed in the fourth direction DR4 and the fifth direction DR5 with respect to the first pixel PX1 disposed at both ends of the first direction DR1. However, the arrangement of the different pixels PX1, PX2, and PX3 in the pixel group PXG is not limited thereto. The arrangement of the different pixels PX1, PX2, and PX3 may be related to the arrangement of the plurality of emission areas EA1, EA2, EA3, and EA4 having different opening widths from each other. A detailed description thereof will be given later.

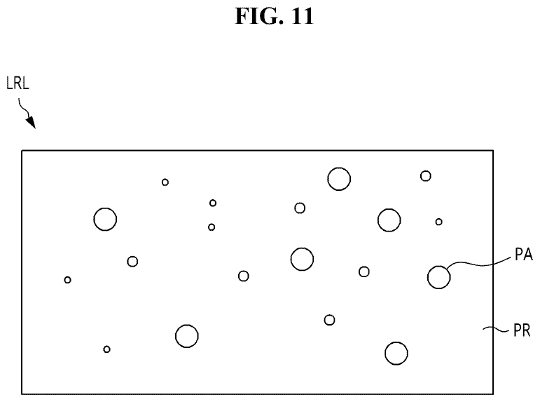

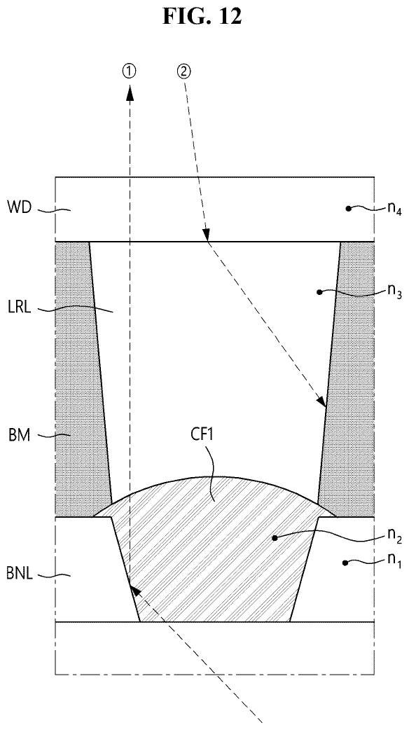

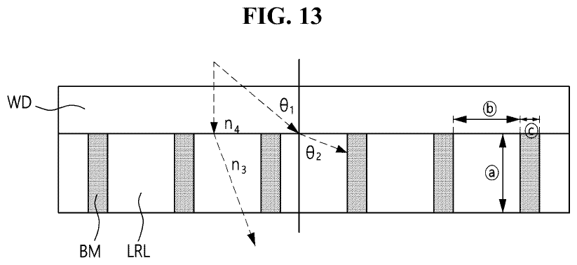

FIG. 10 is a cross-sectional view taken along line X-X′ of FIG. 8. FIG. 11 is a schematic cross-sectional view of a low refractive layer according to an embodiment. FIG. 12 is a cross-sectional view schematically illustrating a reflection reduction layer according to an embodiment. FIG. 13 is a cross-sectional view schematically illustrating a light blocking layer, a low refractive layer, and a window according to an embodiment. Here, FIG. 10 illustrates a cross section crossing the first emission area EA1, the third emission area EA3, and the second emission area EA2.

A cross-sectional structure of the display device 10 will be described with reference to FIGS. 10 to 13 in addition to FIGS. 8 and 9.

The display panel 100 of the display device 10 according to an embodiment may include the display layer DU, the touch sensing layer TSU, a reflection reduction layer (or anti-reflection layer) RPL, and a window WD. The display layer DU may include the substrate SUB, the thin film transistor layer TFTL, the light emitting element layer EML, and the encapsulation layer TFEL. The display panel 100 may include the reflection reduction layer RPL disposed on the touch sensing layer TSU. The reflection reduction layer RPL may include a bank layer BNL, a light blocking layer BM, a color filter layer CF, and a low refractive layer LRL.

The substrate SUB may be a base substrate or a base member. The substrate SUB may be a flexible substrate which can be bent, folded or rolled. In an embodiment, for example, the substrate SUB may include a polymer resin such as polyimide (PI), but is not limited thereto. In another embodiment, for example, the substrate SUB may include a glass material or a metal material.

The thin film transistor layer TFTL may include a first buffer layer BF1, a lower metal layer BML, a second buffer layer BF2, a thin film transistor TFT, a gate insulating layer GI, a first interlayer insulating layer ILD1, a capacitor electrode CPE, a second interlayer insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic layer capable of preventing penetration of air or moisture. In an embodiment, for example, the first buffer layer BF1 may include a plurality of inorganic layers alternately stacked.

The lower metal layer BML may be disposed on the first buffer layer BF1. For example, the lower metal layer BML may be formed as a single layer or multiple layers including or made of at least one selected from molybdenum (Mo), aluminum (Al), chromium (Cr), gold (Au), titanium (Ti), nickel (Ni), neodymium (Nd), tantalum (Ta), and copper (Cu) or an alloy thereof.

The second buffer layer BF2 may cover the first buffer layer BF1 and the lower metal layer BML. The second buffer layer BF2 may include an inorganic layer capable of preventing penetration of air or moisture. In an embodiment, for example, the second buffer layer BF2 may include a plurality of inorganic layers alternately stacked.

The thin film transistor TFT may be disposed on the second buffer layer BF2, and may constitute a pixel circuit of each of a plurality of pixels. In an embodiment, for example, the thin film transistor TFT may be a switching transistor or a driving transistor of the pixel circuit. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction, and may be insulated from the gate electrode GE by the gate insulating layer GI. In a portion of the semiconductor layer ACT, a material of the semiconductor layer ACT may be made into a conductor to form the source electrode SE and the drain electrode DE.

The gate electrode GE may be disposed on the gate insulating layer GI. The gate electrode GE may overlap the semiconductor layer ACT with the gate insulating layer GI interposed therebetween.

The gate insulating layer GI may be disposed on the semiconductor layer ACT. In an embodiment, for example, the gate insulating layer GI may cover the semiconductor layer ACT and the second buffer layer BF to insulate the gate electrode GE from the semiconductor layer ACT. The gate insulating layer GI may be provided with a contact hole through which the first connection electrode CNE1 extends.

The first interlayer insulating layer ILD1 may cover the gate electrode GE and the gate insulating layer GI. The first interlayer insulating layer ILD1 may be provided with a contact hole through which the first connection electrode CNE1 extends. The contact hole of the first interlayer insulating layer ILD1 may be connected to the contact hole of the gate insulating layer GI and the contact hole of the second interlayer insulating layer ILD2.

The capacitor electrode CPE may be disposed on the first interlayer insulating layer ILD1. The capacitor electrode CPE may overlap the gate electrode GE in the thickness direction. The capacitor electrode CPE and the gate electrode GE may form a capacitance.

The second interlayer insulating layer ILD2 may cover the capacitor electrode CPE and the first interlayer insulating layer ILD1. The second interlayer insulating layer ILD2 may be provided with a contact hole through which the first connection electrode CNE1 extends. The contact hole of the second interlayer insulating layer ILD2 may be connected to the contact hole of the first interlayer insulating layer ILD1 and the contact hole of the gate insulating layer GI.

The first connection electrode CNE1 may be disposed on the second interlayer insulating layer ILD2. The first connection electrode CNE1 may electrically connect the drain electrode DE of the thin film transistor TFT to the second connection electrode CNE2. The first connection electrode CNE1 may be inserted into a contact hole provided in the second interlayer insulating layer ILD2, the first interlayer insulating layer ILD1, and the gate insulating layer GI to be in contact with the drain electrode DE of the thin film transistor TFT.

The first passivation layer PAS1 may cover the first connection electrode CNE1 and the second interlayer insulating layer ILD2. The first passivation layer PAS1 may protect the thin film transistor TFT. The first passivation layer PAS1 may be provided with a contact hole through which the second connection electrode CNE2 extends.

The second connection electrode CNE2 may be disposed on the first passivation layer PAS1. The second connection electrode CNE2 may electrically connect the first connection electrode CNE1 to a pixel electrode AE of the light emitting element ED. The second connection electrode CNE2 may be inserted into a contact hole formed in the first passivation layer PAS1 to be in contact with the first connection electrode CNE1.

The second passivation layer PAS2 may cover the second connection electrode CNE2 and the first passivation layer PAS1. The second passivation layer PAS2 may include a contact hole through which the pixel electrode AE of the light emitting element ED passes.

The light emitting element layer EML may be disposed on the thin film transistor layer TFTL. The light emitting element layer EML may include the light emitting element ED and a pixel defining layer PDL. The light emitting element ED may include the pixel electrode AE, a light emitting layer EL, and a common electrode CE.

The pixel electrode AE may be disposed on the second passivation layer PAS2. The pixel electrode AE may be disposed to overlap a corresponding one of the openings OPE1, OPE2, OPE3, and OPE4 of the pixel defining layer PDL. The pixel electrode AE may be electrically connected to the drain electrode DE of the thin film transistor TFT through the first and second connection electrodes CNE1 and CNE2.

The light emitting layer EL may be disposed on the pixel electrode AE. For example, the light emitting layer EL may be an organic light emitting layer including or made of an organic material, but is not limited thereto. In an embodiment where the organic light emitting layer is employed as the light emitting layer EL, the thin film transistor TFT applies a predetermined voltage to the pixel electrode AE of the light emitting element ED, and if the common electrode CE of the light emitting element ED receives a common voltage or a cathode voltage, the holes and electrons can move to the light emitting layer EL through the hole transporting layer and the electron transporting layer and combine to produce light to be emitted by the light emitting layer EL.

The common electrode CE may be arranged on the light emitting layer EL. In an embodiment, for example, the common electrode CE may be provided in the form of an electrode common to all of the pixels rather than specific to each of the pixels. The common electrode CE may be disposed on the light emitting layer EL in the first to fourth emission areas EA1, EA2, EA3, and EA4, and may be disposed on the pixel defining layer PDL in an area other than the first to fourth emission areas EA1, EA2, EA3, and EA4.

The common electrode CE may receive the common voltage or a low potential voltage. When the pixel electrode AE receives a voltage corresponding to a data voltage and the common electrode CE receives the low potential voltage, a potential difference is formed between the pixel electrode AE and the common electrode CE, so that the light emitting layer EL may emit light.

The pixel defining layer PDL may define the plurality of openings OPE1, OPE2, OPE3, and OPE4, and may be disposed on a portion of the second passivation layer PAS2 and the pixel electrode AE. The pixel defining layer PDL may define the first opening OPE1, the second opening OPE2, the third opening OPE3, and the fourth opening OPE4, and each of the openings OPE1, OPE2, OPE3, and OPE4 may expose a portion of the pixel electrode AE. In an embodiment, as described above, each of the openings OPE1, OPE2, OPE3, and OPE4 of the pixel defining layer PDL may define the first to fourth emission areas EA1, EA2, EA3, and EA4, and the areas or sizes of the openings OPE1, OPE2, OPE3, and OPE4 may be different from each other. The pixel defining layer PDL may separate and insulate the pixel electrode AE of each of the plurality of light emitting elements ED.

The pixel defining layer PDL may include a light absorbing material to prevent light reflection. In an embodiment, for example, the pixel defining layer PDL may include a polyimide (PI)-based binder and a pigment in which red, green, and blue colors are mixed. Alternatively, the pixel defining layer PDL may include a cardo-based binder resin and a mixture of a lactam black pigment and a blue pigment. Alternatively, the pixel defining layer PDL may include carbon black.

The encapsulation layer TFEL may be disposed on the common electrode CE to cover the plurality of light emitting elements ED. The encapsulation layer TFEL may include at least one inorganic layer to prevent oxygen or moisture from penetrating into the light emitting element layer EML. The encapsulation layer TFEL may include at least one organic layer to protect the light emitting element layer EML from foreign matters such as dust.

In an embodiment, the encapsulation layer TFEL may include a first encapsulation layer TFE1, a second encapsulation layer TFE2, and a third encapsulation layer TFE3. The first encapsulation layer TFE1 and the third encapsulation layer TFE3 may be inorganic encapsulation layers, and the second encapsulation layer TFE2 disposed between the first encapsulation layer TFE1 and the third encapsulation layer TFE3 may be an organic encapsulation layer.

Each of the first encapsulation layer TFE1 and the third encapsulation layer TFE3 may include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The second encapsulation layer TFE2 may include a polymer-based material. Examples of the polymer-based material may include acrylic resin, epoxy resin, polyimide, polyethylene or the like. In an embodiment, for example, the organic encapsulation layer 320 may include an acrylic resin, such as polymethyl methacrylate, polyacrylic acid, or the like. The second encapsulation layer TFE2 may be formed by curing a monomer or applying a polymer.

The touch sensing layer TSU may be disposed on the encapsulation layer TFEL. The touch sensing layer TSU may include a touch insulating layer SIL, a touch electrode TL, and an overcoat layer OC.

The touch insulating layer SIL may be disposed on the encapsulation layer TFEL. The touch insulating layer SIL may have an insulating and optical function. The touch insulating layer SIL may include at least one inorganic layer or organic layer. Alternatively, the touch insulating layer SIL may be omitted. Another layer of a touch electrode may be further disposed on the touch insulating layer SIL.

A portion of the touch electrode TL may be disposed on the touch insulating layer SIL. Each of the touch electrodes TL may not overlap the first to fourth emission areas EA1, EA2, EA3, and EA4. Each of the touch electrodes TL may be formed of a single layer including molybdenum (Mo), titanium (Ti), copper (Cu), tantalum (Ta), aluminum (Al), or indium tin oxide (ITO), or may be formed to have a stacked structure (Ti/Al/Ti) of aluminum and titanium, a stacked structure (ITO/Al/ITO) of aluminum and ITO, an Ag—Pd—Cu (APC) alloy, or a stacked structure (ITO/APC/ITO) of APC alloy and ITO.

The overcoat layer OC may cover the touch electrode TL and the touch insulating layer SIL. The overcoat layer OC may have an insulating and optical function. Further, the overcoat layer OC may have a function of flattening a lower step. The overcoat layer OC may include an organic material, and may include, for example, polyimide (PI).

The reflection reduction layer RPL may be disposed on the touch sensing layer TSU. The reflection reduction layer RPL may include the bank layer BNL, the color filter layer CF, the light blocking layer BM, and the low refractive layer LRL. The display device 10 according to an embodiment may include the reflection reduction layer RPL that is implemented with the bank layer BNL, the color filter layer CF, the light blocking layer BM, and the low refractive layer LRL. Thus, a conventional polarization layer attached onto the display layer DU via a separate bonding member, such as a pressure sensitive adhesive (PSA) or an optical clear adhesive (OCA), may be omitted.

In an embodiment, the bank layer BNL may be disposed on the overcoat layer OC of the touch sensing layer TSU. The bank layer BNL defines a plurality of holes arranged to overlap the emission areas EA1, EA2, EA3, and EA4 so that transmittance of light emitted through the emission areas EA1, EA2, EA3, and EA4 is not decreased.

In an embodiment, the bank layer BNL may function to allow light emitted from the light emitting element layer EML to travel to the outside without being absorbed by the upper light blocking layer BM. The lateral side of the bank layer BNL overlapping each of the emission areas EA1, EA2, and EA3 may have a predetermined taper angle. In an embodiment, the bank layer BNL may have a taper angle in a range of about 30° to about 90° so that light emitted from the light emitting element layer EML is refracted. In this case, if the taper angle of the bank layer BNL is about 30° or greater, light emitted from the light emitting element layer EML may be refracted upward, and accordingly the light emission efficiency may be improved. Further, if the taper angle of the bank layer BNL is about 90° or less, it is possible to prevent light emitted from the light emitting element layer EML from being unable to travel upward. Refraction and upward emission of light at the bank layer BNL will be described later in detail with reference to FIG. 11. The bank layer BNL may include a transparent organic material, for example, polyimide (PI) or an acrylic resin.

The color filters CF1, CF2, CF3, and CF4 of the color filter layer CF may be arranged on the bank layer BNL and the overcoat layer OC. In an embodiment, for example, the color filter layer CF may be disposed in (or directly on) a same layer as the bank layer BNL. The different color filters CF1, CF2, CF3, and CF4 may be disposed to correspond to the different emission areas EA1, EA2, EA3, and EA4, respectively. In an embodiment, for example, the first color filter CF1 may be disposed to correspond to the first emission area EA1, the second color filter CF2 may be disposed to correspond to the second emission area EA2, and the third color filter CF3 may be disposed to correspond to the third emission area EA3. Although not illustrated in the drawing, the fourth color filter CF4 may be disposed to correspond to the fourth emission area EA4. The color filters CF1, CF2, CF3, and CF4 may be disposed to have a greater area than the emission areas EA1, EA2, EA3, and EA4, respectively, in a plan view, and some of them may be disposed directly on the bank layer BNL.

The light blocking layer BM may be disposed on the bank layer BNL and the color filter layer CF. The light blocking layer BM may be disposed to cover the conductive line of the touch electrode TL, and may include the plurality of holes OPT1, OPT2, OPT3, and OPT4 disposed to overlap the emission areas EA1, EA2, EA3, and EA4. For example, the first hole OPT1 may be disposed to overlap the first emission area EA1. The second hole OPT2 may be disposed to overlap the second emission area EA2, and the third hole OPT3 may be disposed to overlap the third emission area EA3. Although not illustrated in the drawing, the fourth hole OPT4 may be disposed to overlap the fourth emission area EA4.

The area or size of each of the holes OPT1, OPT2, and OPT3, and OPT4 may be greater than the area or size of the openings OPE1, OPE2, OPE3, and OPE4 of the pixel defining layer PDL. The holes OPT1, OPT2, OPT3, and OPT4 of the light blocking layer BM are formed to be greater than the openings OPE1, OPE2, OPE3, and OPE4 of the pixel defining layer PDL, so that the light emitted from the emission areas EA1, EA2, EA3, and EA4 may be visually recognized by the user not only from the front surface but also from the side surface of the display device 10.

The light blocking layer BM may include a light absorbing material. In an embodiment, for example, the light blocking layer BM may include an inorganic black pigment or an organic black pigment. The inorganic black pigment may be carbon black, and the organic black pigment may include at least one selected from lactam black, perylene black, and aniline black, but they are not limited thereto. The light blocking layer BM may effectively prevent visible light infiltration and color mixture between the first to fourth emission areas EA1, EA2, EA3, and EA4, which leads to the improvement of color reproducibility of the display device 10.

The low refractive layer LRL may be disposed on the color filter layer CF and the light blocking layer BM. The low refractive layer LRL is disposed on the different color filters CF1, CF2, CF3, and CF4 and may be disposed to correspond to the different emission areas EA1, EA2, EA3, and EA4 or the holes OPT1, OPT2, OPT3, and OPT4 of the light blocking layer BM. The low refractive layer LRL may be disposed while being filled in the holes OPT1, OPT2, OPT3, and OPT4 of the light blocking layer BM. The low refractive layer LRL may be disposed to be in direct contact with the color filters CF1, CF2, CF3, and CF4 and the side surface of the light blocking layer BM. The height of the low refractive layer LRL may be the same as the height of the light blocking layer BM. In an embodiment, for example, the top surface of the low refractive layer LRL may be aligned and coincide with the top surface of the light blocking layer BM, that is, the top surface of the low refractive layer LRL and the top surface of the light blocking layer BM may collectively define a continuous top surface of the low refractive layer LRL.

In an embodiment, as shown in FIG. 11, the low refractive layer LRL may include particles PA dispersed in a transparent resin PR.

The resin PR may include at least one selected from acrylic, polysiloxane, polyurethane, polyurethane acrylate, polyimide, polymethylsilsesquioxane (PMSSQ), and polymethyl methacrylate (PMMA).

The particle PA may be a hollow particle. In an embodiment, for example, the particle PA may include at least one selected from silica (SiO₂), magnesium fluoride (MgF₂), and iron oxide (Fe₃O₄). In an embodiment, for example, the particle PA may include a shell including or made of at least one selected from the above materials and a hollow in the shell. In an embodiment, the particle PA may have a diameter in a range of about 20 nanometers (nm) to about 200 nm, and the diameter of the particle PA may determine the thickness of the shell and the diameter of the hollow.

The particles PA may be contained in the low refractive layer LRL in a weight ratio of about 10% to about 50% to the resin PR. When the weight ratio of the particles PA to resin PR is about 10% or greater, the refractive index of the low refractive layer LRL may be reduced. When the weight ratio of the particles PA to resin PR is about 50% or less, deterioration of adhesion to the adjacent layers may be prevented. The low refractive layer LRL may be formed by coating and curing a solution containing a solvent in which the resin PR and the particles PA are dispersed.

Referring back to FIG. 10, the window WD may be disposed on the reflection reduction layer RPL. The window WD may include a rigid material such as glass or quartz. The window WD may be attached onto the reflection reduction layer RPL via an optically transparent adhesive. The window WD may be in direct contact with the low refractive layer LRL and the light blocking layer BM. In an embodiment, for example, the bottom surface of the window WD may be in direct contact with the top surface of the low refractive layer LRL and the top surface of the light blocking layer BM.

In an embodiment, the reflection reduction layer RPL may change an optical path of incident external light, so that the external light may be absorbed by the light blocking layer BM. In such an embodiment, the reflection reduction layer RPL may change a path of light emitted from the light emitting layer EML, so that the light may travel upward.

In an embodiment, as shown in FIG. 12, the bank layer BNL and the color filter CF may have specific or predetermined refractive indices to change the path of light emitted from the light emitting element layer EML. In an embodiment, for example, a refractive index n₁ of the bank layer BNL may be less than a refractive index n₂ of the color filter CF. In an embodiment, the refractive index n₁ of the bank layer BNL may be about 1.5, and the refractive index n₂ of the color filter CF may be about 1.6. In this case, a path of light \textcircled{1} emitted from the light emitting element layer EML may be changed at the interface of the bank layer BNL and the color filter CF due to the difference in refractive index of the bank layer BNL and the color filter CF. Particularly, since the side surface of the bank layer BNL is tapered, the light \textcircled{1} may be reflected and emitted toward the window WD.

In such an embodiment, the low refractive layer LRL may change the path of external light incident through the window WD. In an embodiment, for example, a refractive index n₃ of the low refractive layer LRL may be smaller than a refractive index n₄ of the window WD. In an embodiment, the refractive index n₃ of the low refractive layer LRL may be 0.1 or more less than the refractive index n₄ of the window WD. That is, the refractive index n₃ of the low refractive layer LRL may less than the refractive index n₄ of the window WD, and the difference between the refractive index n₃ of the low refractive layer LRL and the refractive index n₄ of the window WD may be 0.1 or greater. In some embodiments, the refractive index n₃ of the low refractive layer LRL may be about 1.2, and the refractive index n₄ of the window WD may be about 1.46. In this case, a path of external light \textcircled{2} incident from the outside may be changed at the interface of the window WD and the low refractive layer LRL due to the difference in refractive index of the window WD and the low refractive layer LRL. Particularly, the external light \textcircled{2} may be refracted toward the light blocking layer BM, and thus the refracted external light \textcircled{2} may be absorbed by the light blocking layer BM.

In an embodiment, the height, width, and interval of the light blocking layer BM may be set to absorb external light.

Referring to FIG. 13, an optical filter characteristic of the light blocking layer BM may be adjusted according to (or determined based on) a height \textcircled{a}, a width \textcircled{b} and an interval \textcircled{c}. In this case, the optical filter characteristic of the light blocking layer BM may represent the degree of blocking external light (light blocking characteristic) and the degree of emitting light emitted from the inside (light emission characteristic). As the height \textcircled{a} of the light blocking layer BM increases, the light blocking characteristic for external light increases, but the light emission characteristic for internal light decrease. In other words, as a ratio of the height \textcircled{a} to the interval \textcircled{c} of the light blocking layer BM is close to 1, the filter characteristic may exhibit optimal efficiency. However, as the ratio of the height \textcircled{a} to the interval \textcircled{c} of the light blocking layer BM is close to 1, the width \textcircled{b} of the light blocking layer BM increases, and thus the luminance decreases. Therefore, it is desired to set the ratio of the height \textcircled{a} to the interval \textcircled{c} of the light blocking layer BM to be less than 1 by setting the refractive indices of the window WD and the low refractive layer LRL to be different from each other to minimize the width \textcircled{b} of the light blocking layer BM.

An emission angle θ₂ to an incident angle θ₁ of light may be expressed by Equation 1 below.

$${θ}_{2} = {sin}^{- 1} ( \frac{{n}_{2}}{{n}_{1}} sin {θ}_{1} ) \qquad [ Equation 1 ]$$

The refractive index n₄ of the window WD corresponds to n₁ in Equation 1, and the refractive index n₃ of the low refractive layer LRL corresponds to n₂ in Equation 1.

The height \textcircled{a} and interval \textcircled{c} of the light blocking layer BM and the emission angle θ₂ may be expressed by Equation 2 below.

$$= tan ( 90 - {θ}_{2} ) \qquad [ Equation 2 ]$$

In an embodiment, the ratio of the height \textcircled{a} to the interval \textcircled{c} of the light blocking layer BM may be set by Equations 1 and 2 based on the refractive indices of the window WD and the low refractive layer LRL, thereby adjusting the external light blocking characteristic and the light emission characteristic of the display device 10.

As described above, since the display device 10 according to an embodiment includes the reflection reduction layer RPL, it is possible to increase the light emission efficiency of internal light and decrease the reflection of external light, thereby improving the display quality.

Hereinafter, other embodiments of the display device 10 will be described with reference to other drawings.

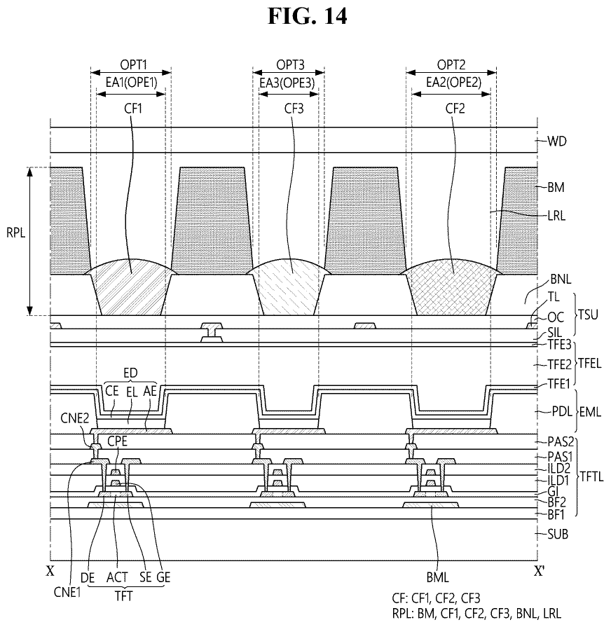

FIG. 14 is a cross-sectional view schematically illustrating a display device according to another embodiment.

Referring to FIG. 14, the embodiment of FIG. 14 is substantially the same as the embodiment of FIGS. 10 to 13 described above except that the low refractive layer LRL covers the light blocking layer BM. Accordingly, any repetitive detailed description of the same or like elements as those of the above-described embodiments will be omitted while focusing on differences.

In an embodiment, as shown in FIG. 14, the low refractive layer LRL may be disposed on the color filter layer CF and the light blocking layer BM. The low refractive layer LRL may cover the color filter layer CF and the light blocking layer BM. In an embodiment, for example, the low refractive layer LRL may completely cover the color filter layer CF and the light blocking layer BM. In an embodiment, the low refractive layer LRL may be in contact with the side and top surface of the light blocking layer BM. The top surface of the low refractive layer LRL may be disposed to be spaced apart from the top surface of the light blocking layer BM in the thickness direction. When measured from the substrate SUB, the top surface of the low refractive layer LRL may be higher than the top surface of the light blocking layer BM.

The low refractive layer LRL may function not only to change the optical path of external light so that the external light is absorbed by the light blocking layer BM, but also to flatten the lower portion so that the window WD properly adheres. The low refractive layer LRL is disposed to completely cover the light blocking layer BM to have a flat top surface, thereby increasing adhesion to the window WD.

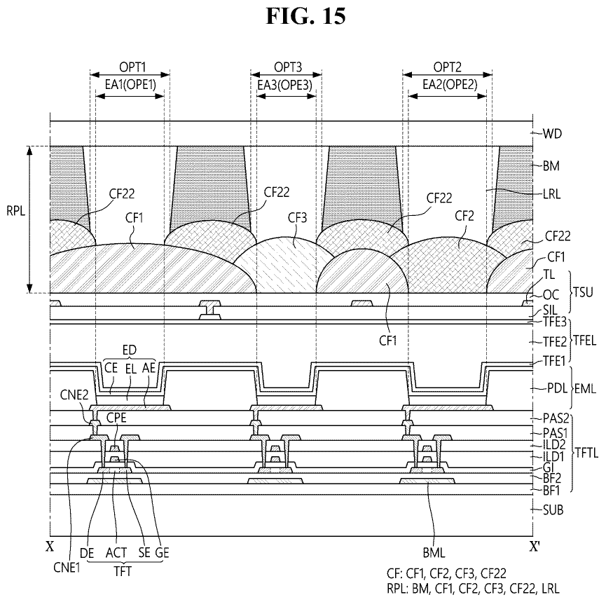

FIG. 15 is a cross-sectional view schematically illustrating a display device according to still another embodiment.

Referring to FIG. 15, the embodiment of FIG. 15 is substantially the same as the embodiments of FIGS. 10 to 14 described above except that the bank layer BNL is omitted and the color filter CF functions as the light blocking layer.

In an embodiment, as shown in FIG. 15, the color filter layer CF may be disposed on the overcoat layer OC. The color filter layer CF may include the first color filter CF1, the second color filter CF2, the third color filter CF3, and a color pattern CF22. Although not shown, the color filter layer CF may further include the fourth color filter CF4.

The first color filter CF1 may be disposed to correspond to the first emission area EA1, the second color filter CF2 may be disposed to correspond to the second emission area EA2, and the third color filter CF3 may be disposed to correspond to the third emission area EA3. In such an embodiment, the first color filter CF1 may be disposed to correspond to the pixel defining layer PDL of the light emitting element layer EML. The first color filter CF1 may be disposed to overlap the pixel defining layer PDL. In an embodiment, for example, the first color filter CF1 may be disposed not only in a region corresponding to the first emission area EA1, but also between the second color filter CF2 and the third color filter CF3. That is, the second color filter CF2 may be disposed between the first color filters CF1, and the third color filter CF3 may be disposed between the first color filters CF1.

In an embodiment, the first color filter CF1 may be disposed to overlap the light blocking layer BM while overlapping the pixel defining layer PDL. The first color filter CF1 may overlap the first emission area EA1, and may also overlap the light blocking layer BM in a plan view. In an embodiment, for example, the arrangement of the first color filter CF1 may include the arrangement of the light blocking layer BM in a plan view.

The color pattern CF22 may be disposed on the first color filter CF1, the second color filter CF2, and the third color filter CF3. The color pattern CF22 may be disposed to overlap the light blocking layer BM while not overlapping the emission areas EA1, EA2, and EA3. The color pattern CF22 may include a same material as the second color filter CF2. In an embodiment, for example, the color pattern CF22 may be a blue color filter that transmits only the second light of the blue color.

The color pattern CF22 may be disposed to overlap the first color filter CF1. In an embodiment, for example, the color pattern CF22 may overlap the first color filter CF1 in an area not overlapping the emission areas EA1, EA2, and EA3. In such an embodiment where the first color filter CF1 overlaps the color pattern CF22, the first color filter CF1 and the color pattern CF22 may serve or function as the light blocking layer BM. In an embodiment, for example, the first color filter CF1 may be a red color filter that transmits only the first light of the red color, and the color pattern CF22 may be a blue color filter that transmits only the second light of the blue color. In such an embodiment, when light is incident on the color pattern CF22, only the second light of the blue color may be transmitted therethrough, and the second light of the blue color may be incident on the first color filter CF1 to be blocked. In other words, when the first color filter CF1 and the color pattern CF22 overlap each other, they may block light.

The light blocking layer BM may be disposed on the color pattern CF22. For example, the light blocking layer BM may be in contact with a top surface of the color pattern CF22, and may be disposed to be spaced apart from the color filters CF1, CF2, and CF3. The low refractive layer LRL may be disposed on the color filters CF1, CF2, and CF3, the color pattern CF22, and the light blocking layer BM. The low refractive layer LRL may be disposed to be in contact with each of the color filters CF1, CF2, and CF3, the color pattern CF22, and the light blocking layer BM.

In an embodiment, the first color filter CF1 and the color pattern CF22 are disposed to overlap each other to serve as a light blocking layer that blocks light, thereby absorbing light incident from the outside, and thus reducing the external light reflection characteristic.

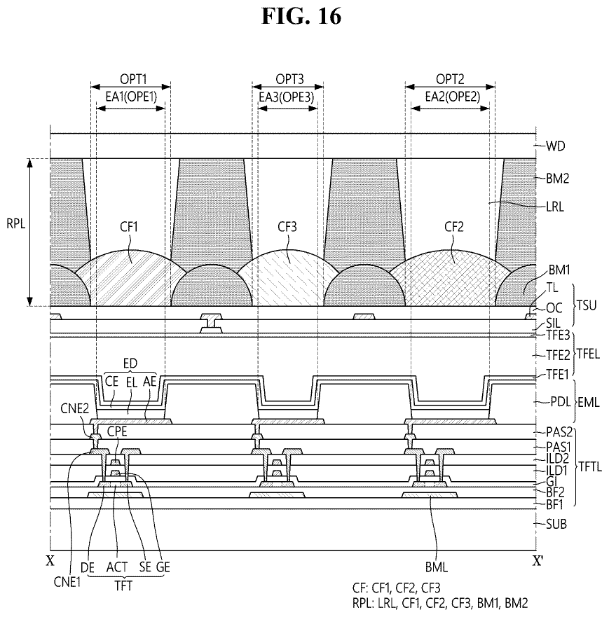

FIG. 16 is a cross-sectional view schematically illustrating a display device according to still another embodiment.

Referring to FIG. 16, the embodiment of FIG. 16 is substantially the same as the embodiments of FIGS. 10 to 14 described above except that a first light blocking layer BM1 is included instead of the bank layer BNL.

In an embodiment, as shown in FIG. 16, the reflection reduction layer RPL may include the first light blocking layer BM1, the color filters CF1, CF2, and CF3, a second light blocking layer BM2, and the low refractive layer LRL.

The first light blocking layer BM1 may be disposed on the overcoat layer OC of the touch sensing layer TSU. The first light blocking layer BM1 may be disposed to cover the conductive line of the touch electrode TL, while including the plurality of holes OPT1, OPT2, OPT3, and OPT4 that overlap the emission areas EA1, EA2, and EA3. The first light blocking layer BM1 may be disposed to overlap the pixel defining layer PDL of the light emitting element layer EML, and may be disposed to surround the emission areas EA1, EA2, and EA3.

The first light blocking layer BM1 may define the first hole OPT1, the second hole OPT2, and the third hole OPT3. The first hole OPT1 may be disposed to overlap the first emission area EA1. The second hole OPT2 may be disposed to overlap the second emission area EA2, and the third hole OPT3 may be disposed to overlap the third emission area EA3.

The color filters CF1, CF2, and CF3 of the color filter layer CF may be disposed on the first light blocking layer BM1 and the overcoat layer OC. The different color filters CF1, CF2, and CF3 may be disposed to correspond to the different emission areas EA1, EA2, and EA3, respectively, and each of the color filters CF1, CF2, and CF3 may be disposed between the first light blocking layers BM1.

The second light blocking layer BM2 may be disposed on the first light blocking layer BM1 and the color filters CF1, CF2, and CF3. The second light blocking layer BM2 may be disposed to overlap the first light blocking layer BM1 without overlapping the plurality of holes OPT1, OPT2, and OPT3. The lateral side of the second light blocking layer BM2 may be aligned and coincide with the lateral side of the first light blocking layer BM1. In an embodiment, for example, the arrangement of the second light blocking layer BM2 may be substantially the same as the arrangement of the first light blocking layer BM1 in plan view.

In such an embodiment, the first light blocking layer BM1 and the second light blocking layer BM2 may be disposed to overlap each other to cover a path of external light that is incident after being refracted at the interface of the low refractive layer LRL and the window WD. Accordingly, the external light blocking characteristic is further improved, thereby reducing the external light reflection characteristic.

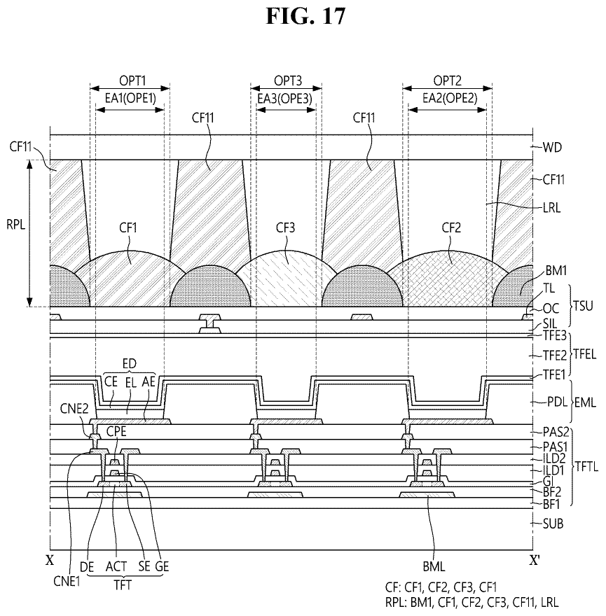

FIG. 17 is a cross-sectional view schematically illustrating a display device according to still another embodiment.

Referring to FIG. 17, the embodiment of FIG. 17 is substantially the same as the embodiment of FIG. 16 described above except that a color pattern CF11 is included instead of the second light blocking layer BM2.

In an embodiment, as shown in FIG. 17, the color pattern CF11 may be disposed on the first light blocking layer BM1 and the color filters CF1, CF2, and CF3. The color pattern CF11 may be disposed to overlap the first light blocking layer BM1 without overlapping the plurality of holes OPT1, OPT2, and OPT3. The lateral side of the color pattern CF11 may be aligned and coincide with the lateral side of the first light blocking layer BM1. For example, the arrangement of the color pattern CF11 may be substantially the same as the arrangement of the first light blocking layer BM1.

The color pattern CF11 may include a same material as the first color filter CF1. In an embodiment, for example, the color pattern CF11 may be a red color filter that transmits only the first light of the red color. In such an embodiment where the color pattern CF11 is formed as a red color filter, it is possible to prevent a phenomenon in which the visibility of reflected external light in the display device 10 is bluish from occurring. In an embodiment, for example, when external light is incident and passes through the color pattern CF11, the external light is converted into red light, and the red light is reflected in the display device 10 and emitted to the outside. That is, since blue light is removed from the wavelength of light emitted to the outside, and the light is converted into red light instead to be emitted to the outside, the bluish visibility characteristic may be improved.

Although not shown, when the visibility of reflected external light in the display device is reddish, the color pattern CF11 may be formed as a blue color filter. Further, when the visibility of reflected external light in the display device is greenish, the color pattern CF11 may be formed as a blue or red color filter.

In an embodiment, as described above, by forming the color pattern CF11 on the first light blocking layer BM1 and the color filters CF1, CF2, and CF3, it is possible to reduce the phenomenon in which the visibility of reflected external light represents a specific color, thereby improving the visibility of reflected external light.

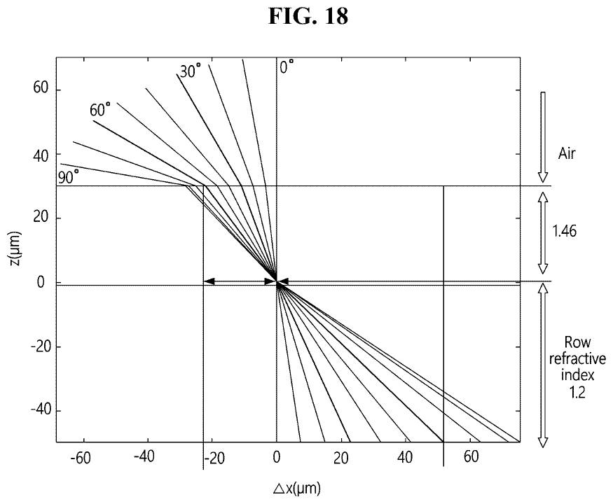

FIG. 18 is a diagram illustrating an optical path of external light incident on a display device.

FIG. 18 shows results obtained by simulating an incident path of external light when a window and a low refractive layer are provided according to an embodiment of the disclosure. In FIG. 18, ‘air’ represents the exterior of the display device, a region marked with ‘1.46’ represents a window having a refractive index of 1.46, and a region marked with ‘low refractive index’ represents a low refractive layer having a refractive index of 1.2. Further, a horizontal axis represents a distance in an X-axis (horizontal) direction and a vertical axis represents a distance in a Z-axis (vertical) direction.

Referring to FIG. 18, when external light is incident at an incidence angle in a range of 0° to 90°, the external light is refracted due to a difference in refractive index at the interface of the air layer and the window, and is refracted due to a difference in refractive index at the interface of the window and the low refractive layer. When the incident angle of the external light is 0°, a moving distance of the path of external light is zero in the X-axis direction, in the low refractive layer. When the incident angle of the external light is 30°, the moving distance of the path of external light is about 23 μm in the X-axis direction, in the low refractive layer. When the incident angle thereof is 60°, the moving distance of the path of external light is about 52 μm in the X-axis direction, in the low refractive layer.

As described above with reference to FIG. 18, it was confirmed that the incident path of external light may be further moved in the X-axis direction by forming the low refractive layer having a lower refractive index than the window, and accordingly, external light may be effectively blocked by the light blocking layer.

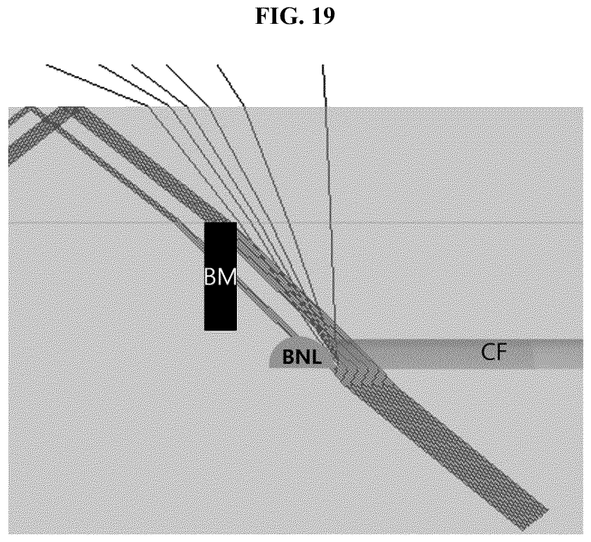

FIG. 19 is a diagram illustrating an emission path of internal light of a display device according to an embodiment.

FIG. 19 shows results obtained by simulating an emission path of internal light emitted from the inside when the color filter CF, the bank layer BNL, and the light blocking layer BM are provided in the display device according to an embodiment shown in FIG. 12.

Referring to FIG. 19, it may be confirmed that a portion of internal light emitted at a specific angle from the inside travels to the light blocking layer BM, while another part thereof is reflected at the interface of the bank layer BNL and the color filter CF and is rerouted in the vertical direction.

As described above with reference to FIG. 19, it was confirmed that internal light is emitted upward by providing the bank layer, and therefore the light emission efficiency may be improved.

The invention should not be construed as being limited to the embodiments set forth herein. Rather, these embodiments are provided so that this disclosure will be thorough and complete and will fully convey the concept of the invention to those skilled in the art

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a light emitting element layer disposed on a substrate, wherein a plurality of emission areas is defined on the light emitting element layer;
an encapsulation layer disposed on the light emitting element layer;
a touch sensing layer disposed on the encapsulation layer, wherein the touch sensing layer comprises a plurality of touch electrodes;
a reflection reduction layer disposed on the touch sensing layer; and
a window disposed on the reflection reduction layer,
wherein the reflection reduction layer comprises:
a color filter layer disposed on the touch sensing layer;
a bank layer disposed on the touch sensing layer between the color filter layers;
a light blocking layer disposed on the bank layer; and
a low refractive layer disposed on the color filter layer, and disposed between the light blocking layer and the color filter layer.

2. The display device of claim 1, wherein a refractive index of the low refractive layer is less than a refractive index of the window.

3. The display device of claim 2, wherein a difference between the refractive index of the low refractive layer and the refractive index of the window is about 0.1 or greater.

4. The display device of claim 1, wherein the low refractive layer comprises a resin and hollow particles dispersed in the resin.

5. The display device of claim 1, wherein a top surface of the low refractive layer and a top surface of the light blocking layer collectively define a continuous top surface of the reflection reduction layer.

6. The display device of claim 1, wherein
the light blocking layer defines a plurality of holes overlapping the plurality of emission areas, and
an area of each of the holes is greater than an area of a corresponding one of the emission areas.

7. The display device of claim 1, wherein
the bank layer and the color filter layer are disposed in a same layer as each other, and
the color filter layer comprises a plurality of color filters.

8. The display device of claim 7, wherein the bank layer has a lateral side overlapping the plurality of emission areas with a taper angle in a range of about 30 degrees to about 90 degrees.

9. The display device of claim 1, wherein a refractive index of the bank layer is less than a refractive index of the color filter layer.

10. The display device of claim 1, wherein
the light emitting element layer comprises a pixel electrode disposed on the substrate, a pixel defining layer covering an edge of the pixel electrode and defining the plurality of emission areas, a light emitting layer disposed on the pixel electrode, and a common electrode disposed on the light emitting layer, and
the light blocking layer and the bank layer overlap the pixel defining layer.

11. The display device of claim 1, wherein the low refractive layer covers the light blocking layer, and is in contact with a top surface of the light blocking layer.

12. A display device comprising:
a light emitting element layer disposed on a substrate, wherein a plurality of emission areas is defined on the light emitting element layer;
an encapsulation layer disposed on the light emitting element layer;
a touch sensing layer disposed on the encapsulation layer, wherein the touch sensing layer comprises a plurality of touch electrodes;
a reflection reduction layer disposed on the touch sensing layer; and
a window disposed on the reflection reduction layer,
wherein the reflection reduction layer comprises:
a color filter layer disposed on the touch sensing layer;
a first light blocking layer disposed on the color filter layer, wherein a plurality of holes is defined through the first light blocking layer to overlap the plurality of emission areas, respectively; and
a low refractive layer disposed on the color filter layer, and disposed between the first light blocking layers.

13. The display device of claim 12, wherein
the plurality of emission areas comprise a first emission area, a second emission area, and a third emission area, and
the color filter layer comprises a first color filter overlapping the first emission area, a second color filter overlapping the second emission area, and a third color filter overlapping the third emission area,
wherein the first color filter transmits red light, the second color filter transmits blue light, and the third color filter transmits green light.

14. The display device of claim 13, wherein
the color filter layer comprises a color pattern disposed between the first color filter and the first light blocking layer, and
the color pattern is a blue color filter which transmits blue light.

15. The display device of claim 14, wherein the color pattern overlaps the first light blocking layer and does not overlap the plurality of emission areas.

16. The display device of claim 13, further comprising:
a second light blocking layer disposed on the touch sensing layer, disposed between the first color filter and the second color filter, between the second color filter and the third color filter, and between the third color filter and the first color filter.

17. The display device of claim 16, wherein the second light blocking layer overlaps the first light blocking layer and does not overlap the plurality of emission areas.

18. A display device comprising:
a light emitting element layer disposed on a substrate, wherein a plurality of emission areas is defined on the light emitting element layer;
an encapsulation layer disposed on the light emitting element layer;
a touch sensing layer disposed on the encapsulation layer, wherein the touch sensing layer comprises a plurality of touch electrodes;
a reflection reduction layer disposed on the touch sensing layer; and
a window disposed on the reflection reduction layer,
wherein the reflection reduction layer comprises:
a color filter layer disposed on the touch sensing layer, wherein the color filter layer comprises a first color filter, a second color filter, and a third color filter, which are spaced apart from each other;
a light blocking layer disposed on the touch sensing layer between the first to third color filters, wherein a plurality of holes is defined through the light blocking layer to overlap the plurality of emission areas, respectively;
a color pattern disposed on the light blocking layer and not overlapping the plurality of holes; and
a low refractive layer disposed on the first to third color filters, and disposed between the color patterns.

19. The display device of claim 18, wherein
the plurality of emission areas comprise a first emission area, a second emission area, and a third emission area,
the first color filter overlaps the first emission area and transmits red light,
the second color filter overlaps the second emission area and transmits blue light, and
the third color filter overlaps the third emission area and transmits green light.

20. The display device of claim 19, wherein the color pattern is a red color filter which transmits red light.
